(19) United States
(12) Patent Application Publication
(10) Pub. No.: US 2026/0105876 A1
(43) Pub. Date: Apr. 16, 2026

(54) LOW POWER ACTIVE MATRIX ORGANIC LIGHT-EMITTING DIODE DISPLAY

(71) Applicant: Kunshan Yunyinggu Electronic Technology Co., Ltd., Kunshan (CN)

(72) Inventors: Jing GU, Kunshan (CN); Yu-Hsun PENG, Kunshan (CN)

(73) Assignee: Kunshan Yunyinggu Electronic Technology Co., Ltd., Kunshan (CN)

(21) Appl. No.: 19/370,965

(22) Filed: Oct. 28, 2025

Related U.S. Application Data
(63) Continuation of application No. PCT/CN2025/126891, filed on Oct. 11, 2025.
(60) Provisional application No. 63/707,247, filed on Oct. 15, 2024.

(51) Int. Cl. G09G 3/20; G09G 3/3258; H10K 59/131

(52) U.S. Cl. CPC G09G 3/2074; G09G 3/3258; H10K 59/131; G09G 2300/0426; G09G 2300/0452; G09G 2300/0804; G09G 2300/0819; G09G 2300/0842; G09G 2310/0286; G09G 2310/06; G09G 2310/08; G09G 2320/0233; G09G 2320/0242; G09G 2320/0257; G09G 2320/043; G09G 2320/0666; G09G 2330/023

(57) ABSTRACT

An apparatus includes an array of light emitting elements. The array of light emitting elements corresponds to an array of pixels arranged in M rows and N columns. A number of the light emitting elements is k times of a number of the pixels. The apparatus includes an array of driving elements configured to drive the array of light emitting elements. A number of the driving elements is k times of a number of the pixels. The apparatus includes x*M gate lines and ((k/x)*N+1) source lines operatively coupled to the array of driving elements. Each of M, N, k, and x is a positive integer. Each source line is operatively coupled to the driving elements configured to drive the light emitting elements that emit lights of a same color.

### CROSS REFERENCE TO RELATED APPLICATION

This application is a continuation of International Application No. PCT/CN2025/126891, filed on Oct. 11, 2025, which claims the benefit of priority to U.S. Provisional Application No. 63/707,247, filed on Oct. 13, 2024, both of which are hereby incorporated by reference in their entireties.

### BACKGROUND

The disclosure relates generally to display technologies, and more particularly, to a low power active matrix organic light-emitting diode display.

An active matrix organic light-emitting diode (AMOLED) panel includes a matrix of self-emissive OLEDs driven by a thin-film transistor (TFT) backplane. Organic light-emitting layers are fabricated by evaporation techniques using fine metal masks (FMMs). Unlike thin-film transistor liquid crystal display (TFT LCD) panels that generally employ a strip-type subpixel layout, AMOLED panels often adopt subpixel rendering (SPR) technology, such as delta or diamond (RGBG) subpixel arrangements, to accommodate stretching requirements of the FMMs. The TFT backplane is correspondingly designed to accommodate the adopted subpixel arrangement. Such delta and diamond arrangements of subpixels simplify the FMM process during manufacturing and improve manufacturing yield.

### SUMMARY

The disclosure relates generally to display technologies, and more particularly, to array design of display panel.

In one example, an apparatus includes an array of light emitting elements corresponding to an array of pixels arranged in M rows and N columns. A number of the light emitting elements is k times of a number of the pixels. The apparatus includes an array of driving elements configured to drive the array of light emitting elements. A number of the driving elements is k times of a number of the pixels. The apparatus includes x*M gate lines and ((k/x)*N+1) source lines operatively coupled to the array of driving elements. Each of M, N, k, and x is a positive integer. Each source line is operatively coupled to the driving elements configured to drive the light emitting elements that emit lights of a same color.

In another example, an apparatus includes an array of light emitting elements corresponding to an array of pixels arranged in M rows and N columns. A number of the light emitting elements is k times of a number of the pixels. The apparatus includes an array of driving elements configured to drive the array of light emitting elements. A number of the driving elements is k times of a number of the pixels. The apparatus includes M gate lines and ((k/x)*N+1) source lines operatively coupled to the array of driving elements. Each of M, N, k, and x is a positive integer. Each source line is operatively coupled to the driving elements configured to drive the light emitting elements that emit lights of a same color.

### BRIEF DESCRIPTION OF THE DRAWINGS

The embodiments will be more readily understood in view of the following description when accompanied by the below figures and wherein like reference numerals represent like elements, wherein:

FIG. 1 is a block diagram illustrating an apparatus including a display and control logic in accordance with an embodiment;

FIG. 2A illustrates a sectional view of a display shown in FIG. 1 in accordance with one embodiment;

FIG. 2B illustrates a sectional view of the display shown in FIG. 2A in accordance with one embodiment;

FIG. 2C illustrates a sectional view of the display shown in FIG. 2A including an array of pixels in accordance with one embodiment;

FIG. 3 is a block diagram illustrating an example of the control logic shown in FIG. 1 in accordance with an embodiment;

FIG. 4A illustrates an example of an array of subpixels in a display in accordance with an embodiment;

FIG. 4B illustrates an example of an array of driving elements in a display in accordance with an embodiment;

FIG. 4C illustrates an example of a display including the array of subpixels shown in FIG. 4A aligned with the array of driving elements shown in FIG. 4B in accordance with an embodiment;

FIG. 5A illustrates an example of an array of subpixels in a display in accordance with an embodiment;

FIG. 5B illustrates an example of an array of driving elements in a display in accordance with an embodiment;

FIG. 5C illustrates an example of a display including the array of subpixels shown in FIG. 5A aligned with the array of driving elements shown in FIG. 5B in accordance with an embodiment;

FIG. 6A illustrates an arrangement of gate lines and source lines for distributive-driving of subpixels in a display in accordance with an embodiment;

FIGS. 6B-6D illustrate displaying images of pure colors by a display in accordance with an embodiment;

FIG. 7A illustrates an arrangement of gate lines and source lines for distributive-driving of subpixels in a display in accordance with an embodiment;

FIGS. 7B-7D illustrate displaying images of pure colors by a display in accordance with an embodiment;

FIG. 8A illustrates an arrangement of gate lines and source lines for distributive-driving of subpixels in a display in accordance with an embodiment;

FIGS. 8B-8D illustrate displaying images of pure colors by a display in accordance with an embodiment;

FIG. 9 illustrates a driving scheme for a display, and examples of driving schemes for a display in accordance with an embodiment;

FIG. 10A illustrates an array of subpixels having a diamond (RGBG) arrangement in a display;

FIG. 10B illustrates an array of driving elements in a display;

FIG. 10C illustrates a display including the array of subpixels shown in FIG. 10A aligned with the array of driving elements shown in FIG. 10B;

FIG. 10D illustrates an arrangement of gate lines and source lines for driving the display shown in FIG. 10C;

FIG. 11A illustrates an array of subpixels having a delta arrangement in a display;

FIG. 11B illustrates an array of driving elements in a display;

FIG. 11C illustrates a display including the array of subpixels shown in FIG. 11A aligned with the array of driving elements shown in FIG. 11B; and

FIG. 11D illustrates an arrangement of gate lines and source lines for driving the display shown in FIG. 11C.

### DETAILED DESCRIPTION

In the following detailed description, numerous specific details are set forth by way of examples in order to provide a thorough understanding of the relevant disclosures. However, it should be apparent to those skilled in the art that the present disclosure may be practiced without such details. In other instances, well known methods, procedures, systems, components, and/or circuitry have been described at a relatively high-level, without detail, in order to avoid unnecessarily obscuring aspects of the present disclosure.

Throughout the specification and claims, terms may have nuanced meanings suggested or implied in context beyond an explicitly stated meaning. Likewise, the phrase “in one embodiment/example” as used herein does not necessarily refer to the same embodiment and the phrase “in another embodiment/example” as used herein does not necessarily refer to a different embodiment. It is intended, for example, that claimed subject matter include combinations of example embodiments in whole or in part.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

An active matrix organic light-emitting diode (AMOLED) panel includes a matrix of self-emissive OLEDs driven by a thin-film transistor (TFT) backplane. Organic light-emitting layers are fabricated by evaporation techniques using fine metal masks (FMMs). Unlike thin-film transistor liquid crystal display (TFT LCD) panels that generally employ a strip-type subpixel layout, AMOLED panels often adopt subpixel rendering (SPR) technology, such as delta or diamond (RGBG) subpixel arrangements, to accommodate the stretching requirements of the FMMs. The TFT backplane is correspondingly designed to accommodate the adopted subpixel arrangement. Such delta and diamond arrangements of subpixels simplify the FMM process during manufacturing and improve manufacturing yield. However, conventional AMOLED panels having a delta or diamond arrangement of subpixels have a common drawback. When displaying pure red or blue images, the source lines undergo frequent toggling between high and low voltages, which results in increased power consumption. This issue becomes more severe as panel resolution increases and remains a challenge in the development of low-power AMOLED displays.

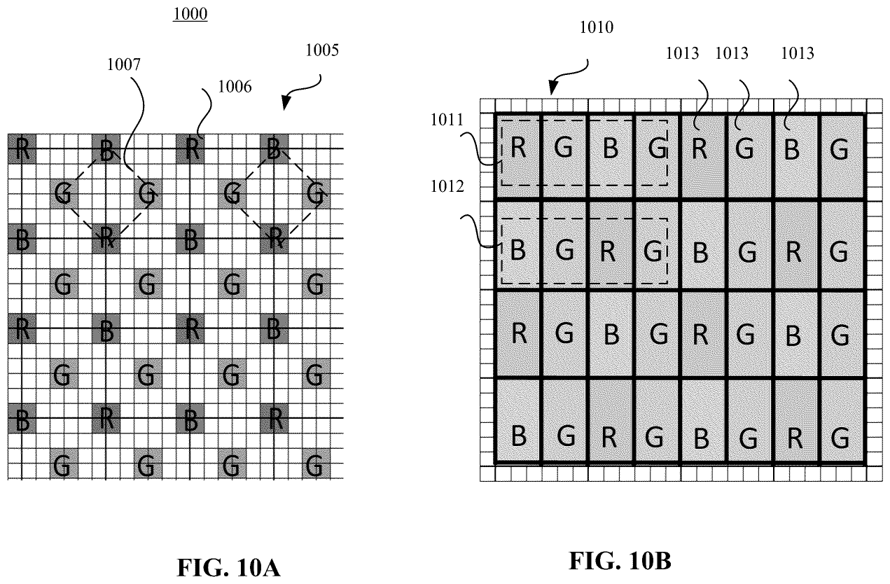

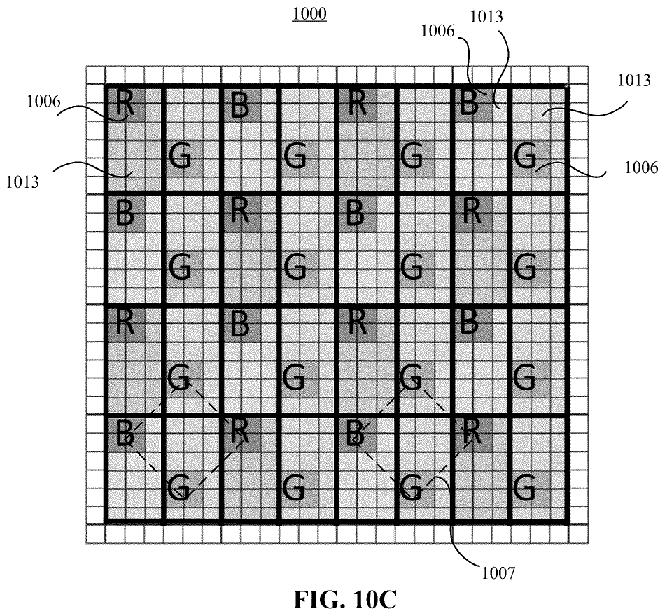

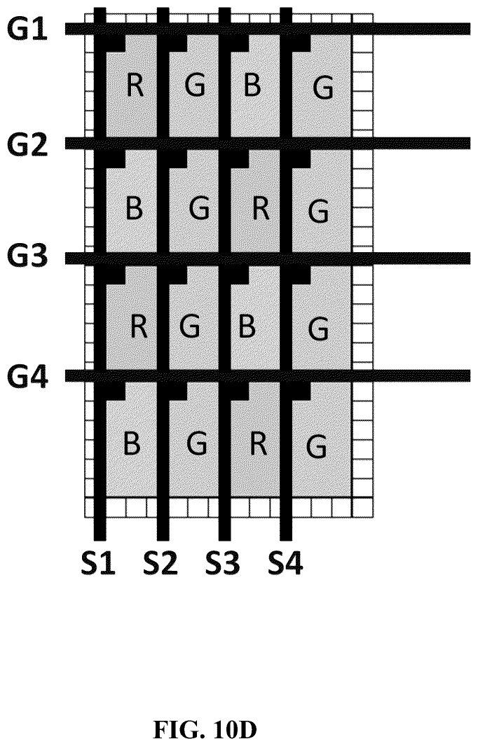

FIG. 10A illustrates an array 1005 of subpixels in a display 1000. The array 1005 of subpixels has a diamond (RGBG) arrangement, where R, G, and B denote red, green, and blue subpixels 1006, respectively. As shown in FIG. 10A, the array 1005 of subpixels corresponds to an array of pixels 1007, and each diamond-shaped “pixel” 1007 includes two green subpixels, one red subpixel, and one blue subpixel. The diamond (RGBG) subpixel arrangement is widely used in small-sized AMOLED panels (e.g., less than 10 inches). FIG. 10B illustrates an array 1010 of driving elements (such as LTPO/LTPS devices) in the display 1000, where R, G, and B denote driving elements 1013 for driving the red, green, and blue subpixels 1006, respectively. The layout of the array 1010 shown in FIG. 10B is designed to accommodate the diamond (RGBG) subpixel arrangement shown in FIG. 10A, and minimize the routing complexity between the driving elements 1013 and the subpixels 1006. As shown in FIG. 10B, the array 1010 includes a first repeating group 1011 of driving elements R-G-B-G applied to odd rows, and a second repeating group 1012 of driving elements B-G-R-G applied to even rows. The driving elements in two adjacent rows aligned with one another.

FIG. 10C illustrates the display 1000 including the array 1005 aligned and superimposed with the array 1010. Referring to FIGS. 10A-10C, each subpixel 1006 is aligned within a driving element for driving the corresponding subpixel. For example, each red, green, or blue subpixel is aligned a driving element for driving the red, green, or blue subpixel. Thus, the routing complexity between the driving elements and the subpixels may be reduced.

FIG. 10D illustrates an arrangement of gate lines and source lines for driving subpixels in a portion of the display 1000. As shown in FIG. 10D, each subpixel row is driven by a single gate line G1, G2, G3, or G4. Every pixel column is driven by two source lines, one of which (e.g., S2 or S4) is coupled to the driving elements G for driving green subpixels, and the other (e.g., S1 or S3) is shared by the driving elements R for driving red subpixels and the driving elements B for driving blue subpixels. Each subpixel row is driven by a single gate line G1, G2, G3, or G4. Thus, a high-definition (HD) AMOLED panel (e.g., resolution is 1920×1080) with the diamond (RGBG) subpixel arrangement requires 2,160 source lines (1080×2) and 1,920 gate lines. When displaying pure red or blue images, the source lines (e.g., S1 or S3) shared by the driving elements R and the driving elements B undergo high-frequency toggling, resulting in increased power consumption.

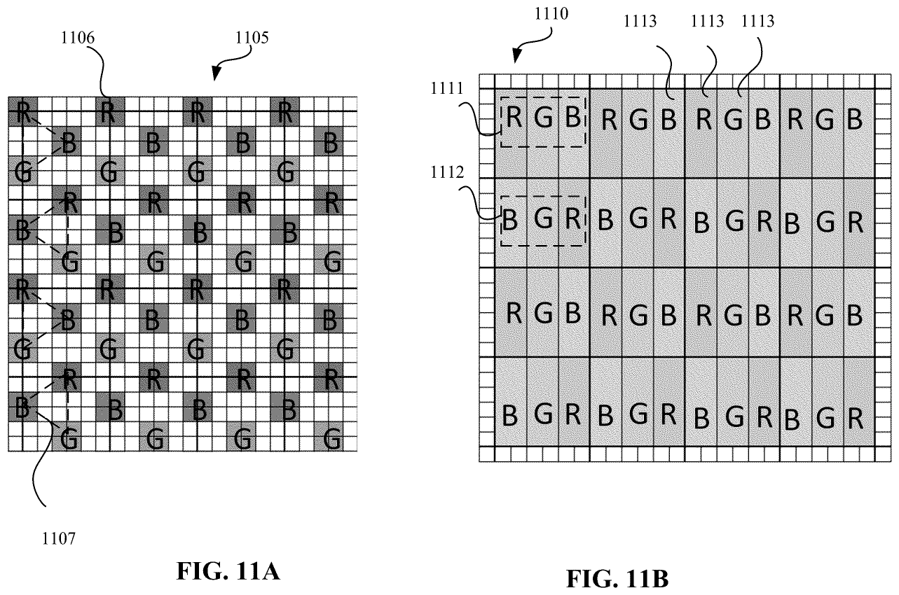

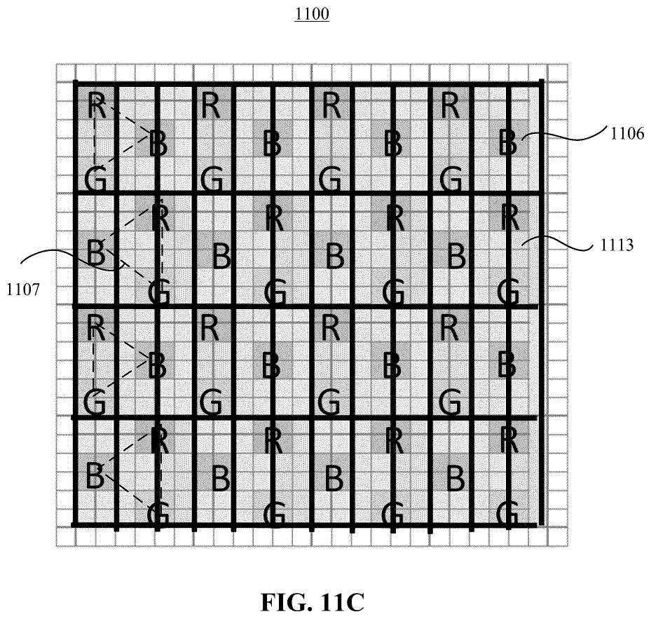

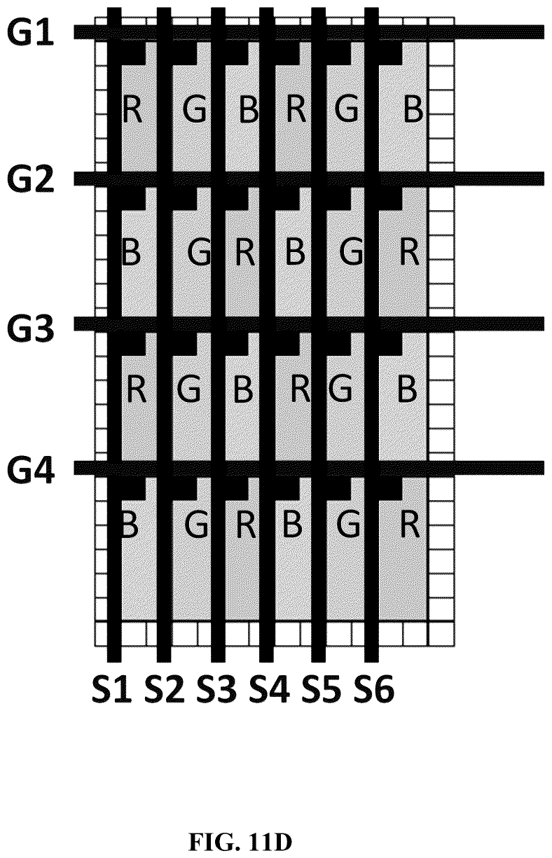

In medium-to large-sized AMOLED panels, a delta arrangement of subpixels is widely used. FIG. 11A illustrates an array 1105 of subpixels in a display 1100. The array 1105 of subpixels has a delta subpixel arrangement, where R, G, and B denote red, green, and blue subpixels 1106, respectively. As shown in FIG. 11A, the array 1105 of subpixels corresponds to an array of pixels 1107, and each “pixel” 1107 includes one green subpixel, one red subpixel, and one blue subpixel arranged in a triangular (delta) pattern. FIG. 11B illustrates an array 1110 of driving elements (e.g., LTPO/LTPS devices) in the display 1100, where R, G, and B denote driving elements 1113 for driving the red, green, and blue subpixels 1106, respectively. As shown in FIG. 11B, the array 1110 includes a first repeating group 1111 of driving elements R-G-B applied to odd rows, and a second repeating group 1112 of driving elements B-G-R applied to even rows. Two adjacent rows of the driving elements in the array 1110 are aligned with one another.

FIG. 11C illustrates the display 1100 in which the array 1105 is aligned and superimposed with the array 1110. The display 1100 is known as a traditional “real-RGB” AMOLED display. Referring to FIGS. 11A-11C, only some blue subpixels and red subpixels are aligned with respective driving elements for the corresponding subpixels, while the remaining red, blue, and green subpixels each is aligned with two adjacent driving elements for two subpixels of different colors. As a result, each pixel requires additional fan-out routing to connect the driving elements to the corresponding subpixels.

FIG. 11D illustrates an arrangement of gate lines and source lines for driving subpixels in a portion of the display 1100. As shown in FIG. 11D, every pixel column is driven by three source lines, one of which (e.g., S2 or S5) is coupled to the driving elements G for driving green subpixels, and the other twos (e.g., S1 and S3, or S4 and S6) are shared by the driving elements R for driving red subpixels and the driving elements B for driving blue subpixels. Thus, an HD AMOLED panel (e.g., resolution is 1920×1080) with the delta subpixel arrangement requires 3,240 source lines (1080×3) and 1,920 gate lines. Similarly, in AMOLED displays with delta subpixel arrangement, when displaying pure red or blue images, the source lines (e.g., S1, S3, S4, or S6) shared by the red and blue subpixels undergo high-frequency toggling, resulting in increased power consumption. The issue becomes more severe as panel resolution increases, and remains a significant challenge in developing low-power AMOLED displays.

The present disclosure provides a display that suppresses high-frequency toggling of source lines, thereby significantly reducing power consumption and improving overall energy efficiency. The display includes an array of subpixels and a corresponding array of driving elements aligned with one another. The subpixel array may be fabricated using fine metal masks (FMMs), where the FMMs originally designed for a traditional “real-RGB” AMOLED display are rotated by 90 degrees. This fabrication approach leverages existing FMM technology while enabling a novel subpixel arrangement that enhances manufacturability, reduces mask redesign costs, and maintains high resolution and image quality.

Further, the array of driving elements may be configured based on the array of subpixels and a distributive-driving scheme. The distributive-driving of the display disclosed herein may reduce the number of source lines or gate lines while maintaining efficient operation. By distributing the driving load to the source and gate lines according to an optimal ratio, the timing characteristics of the display may be improved. In some embodiments, the reduction in the number of source lines is achieved by distributing the driving load based on the specific subpixel arrangement of the display panel, which enables simplified routing and improved panel efficiency. At the same time, the distributive-driving configuration avoids overburdening the gate scan, such as by merely doubling the number of gate lines, and thus prevents substantial reduction of the scan period for each subpixel.

According to some aspects of the present disclosure, in the display panel disclosed herein, each subpixel of a predetermined color is aligned with a corresponding driving element configured to drive that color subpixel, and is not aligned with driving elements configured to drive subpixels of other colors. This configuration significantly reduces the routing complexity between the subpixels and the corresponding driving elements, thereby eliminating the need for additional fan-out routing.

According to some aspects of the present disclosure, through configuring output pins of the source lines with a “zigzag” arrangement, each source line is operatively coupled to the driving elements for subpixels of the same color, without being shared by the driving elements for subpixels of different colors. Thus, when displaying pure red or blue images, the high-frequency toggling of the source lines may be significantly suppressed and, accordingly, the power consumption may be significantly reduced. Since the display of typical color images generally involves fewer high-frequency color switching events than the display of pure red or pure blue images, the overall power consumption for color images is closer to that of pure-color images.

According to some aspects of the present disclosure, the number of gate lines may be reduced to increase the charging time of the source lines by correspondingly increasing the number of source lines. The total number of source and gate lines in the display disclosed herein may be substantially the same as that of a traditional “real-RGB” AMOLED panel, while the metal line layout may be significantly simplified, and the panel's power consumption may be significantly reduced.

According to some aspects of the present disclosure, the compensation time of the pixel circuits in the display disclosed herein may be increased by increasing the number of gate lines and implementing a time-division multiplexing scheme in combination with the distributive-driving scheme. Such a configuration enables each pixel to complete sufficient compensation, thereby enhancing uniformity of luminance and color across the display while preserving overall performance.

Additional novel features will be set forth in part in the description which follows, and in part will become apparent to those skilled in the art upon examination of the following and the accompanying drawings or may be learned by production or operation of the examples. The novel features of the present disclosure may be realized and attained by practice or use of various aspects of the methodologies, instrumentalities, and combinations set forth in the detailed examples discussed below.

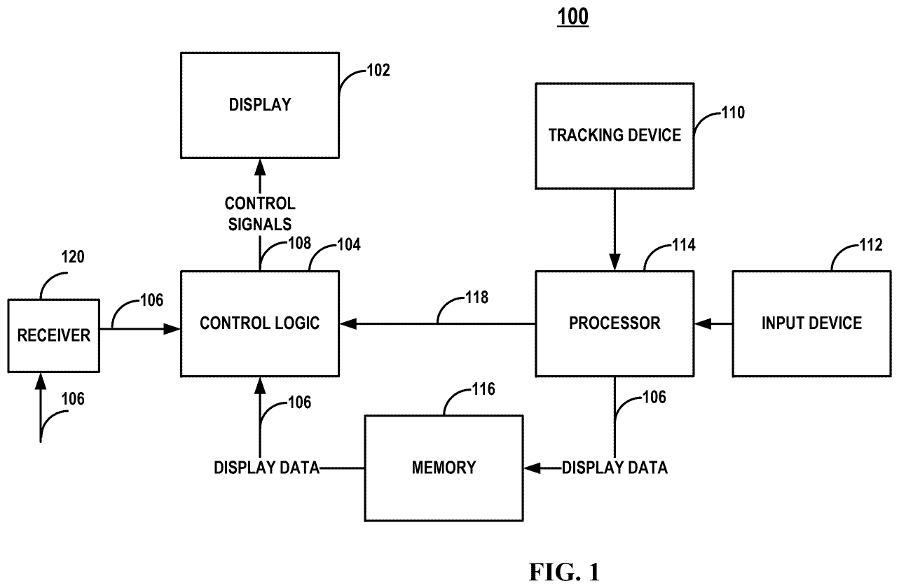

FIG. 1 illustrates an apparatus 100 including a display 102 and control logic 104. The apparatus 100 may be any suitable device, for example, a television set, laptop computer, desktop computer, netbook computer, media center, handheld device (e.g., dumb or smart phone, tablet, etc.), wearable devices (e.g., eyeglasses, wristwatch, etc.), global positioning system (GPS), electronic billboard, electronic sign, gaming console, set-top box, printer, or any other suitable device. In this example, the display 102 is operatively coupled to the control logic 104 and is part of the apparatus 100, such as but not limited to, a television screen, computer monitor, dashboard, head-mounted display, electronic billboard, or electronic sign. The display 102 may be an LCD, OLED display, E-ink display, ELD, billboard display with LED or incandescent lamps, or any other suitable type of display.

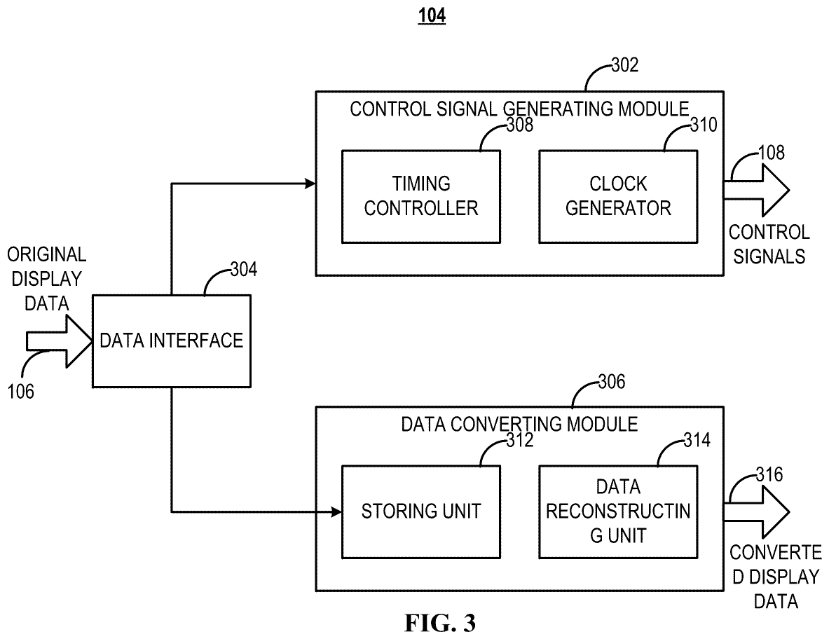

The control logic 104 may be any suitable hardware, software, firmware, or combination thereof, configured to receive display data 106 and render the received display data 106 into control signals 108 for driving subpixels of the display 102. The control signals 108 are used for controlling writing of subpixels and directing operations of the display 102. As described below in detail with respect to FIG. 3, the control logic 104 may include a timing controller, a gate driving module, and a source driving module. The control logic 104 may include any other suitable components, including an encoder, a decoder, one or more processors, controllers, and storage devices. The control logic 104 may be implemented as a standalone integrated circuit (IC) chip, such as a field-programmable gate array (FPGA) or an application-specific integrated circuit (ASIC). The apparatus 100 may also include any other suitable component, such as, but not limited to, a speaker 110 and an input device 112, e.g., a mouse, keyboard, remote controller, handwriting device, camera, microphone, scanner, etc.

In one example, the apparatus 100 may be a laptop or desktop computer having the display 102. In this example, the apparatus 100 also includes a processor 114 and memory 116. The processor 114 may be, for example, a graphics processor (e.g., GPU), a general processor (e.g., APU, accelerated processing unit; GPGPU, general-purpose computing on GPU), or any other suitable processor. The memory 116 may be, for example, a discrete frame buffer or a unified memory. The processor 114 is configured to generate the display data 106 in display frames and temporally store the display data 106 in the memory 116 before sending it to the control logic 104. The processor 114 may also generate other data, such as but not limited to, control instructions 118 or test signals, and provide them to the control logic 104 directly or through the memory 116. The control logic 104 then receives the display data 106 from the memory 116 or from the processor 114 directly.

In another example, the apparatus 100 may be a television set having the display 102. In this example, the apparatus 100 also includes a receiver 120, such as but not limited to, an antenna, radio frequency receiver, digital signal tuner, digital display connectors, e.g., HDMI, DVI, DisplayPort, USB, Bluetooth, WiFi receiver, or Ethernet port. The receiver 120 is configured to receive the display data 106 as an input of the apparatus 100 and provide the native or modulated display data 106 to the control logic 104.

In still another example, the apparatus 100 may be a handheld device, such as a smart phone or a tablet. In this example, the apparatus 100 includes the processor 114, memory 116, and the receiver 120. The apparatus 100 may both generate display data 106 by its processor 114 and receive display data 106 through its receiver 120. For example, the apparatus 100 may be a handheld device that works as both a mobile television and a mobile computing device. In any event, the apparatus 100 at least includes the display 102 with specifically designed subpixel and driving element arrangements as described below in detail.

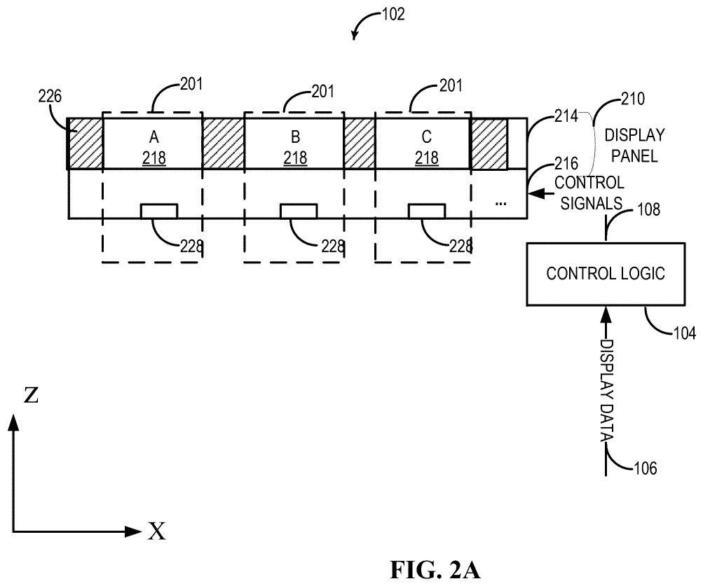

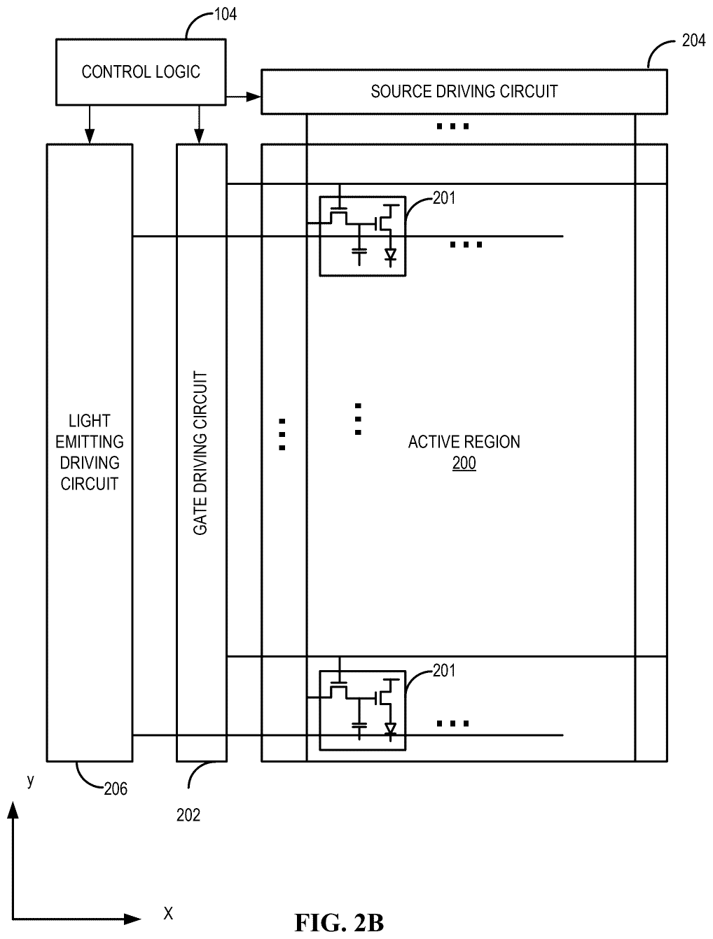

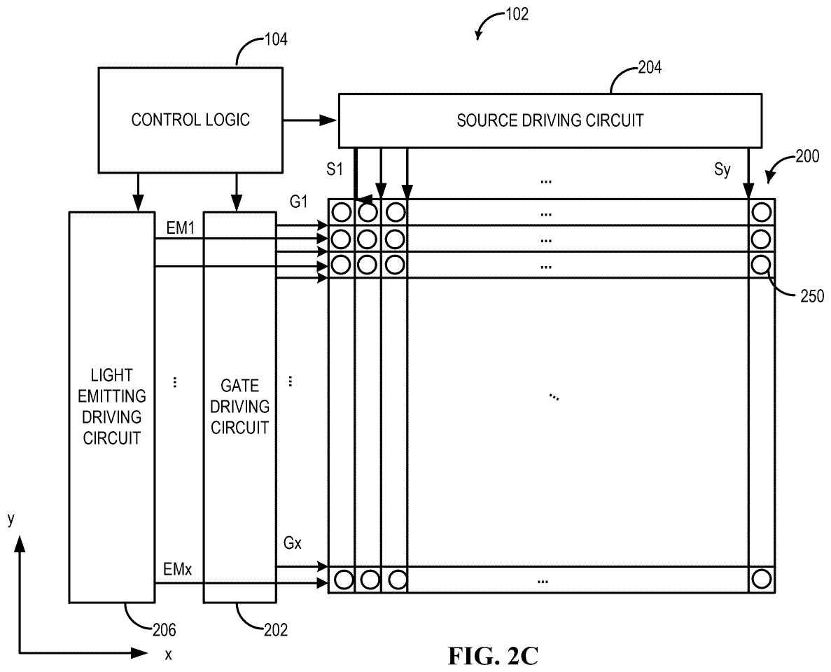

FIG. 2A illustrates an x-z sectional view of one example of the display 102 shown in FIG. 1, and FIG. 2B illustrates an x-y sectional view of the display 102 shown in FIG. 2A. The display 102 may be any suitable type of display, for example, OLED displays, such as an active-matrix OLED (AMOLED) display, passive-matrix (PM) OLED display, or any other suitable display. The display 102 may include a display panel 210 operatively coupled to the control logic 104.

As shown in FIGS. 2A and 2B, the display panel 210 includes an active region 200 including an array of subpixels 201. Each subpixel 201 may be any of the units that make up a pixel, i.e., a subdivision of a pixel. For example, a subpixel 201 may be a single-color display element that can be individually addressed. The active region 200 includes a light emitting layer 214 and a backplane 216. The light emitting layer includes an array of light emitting elements corresponding to the array of subpixels 201. In some embodiments, a single subpixel 201 may include a single light emitting element. In some embodiments, a single subpixel 201 may include two or more light emitting elements that emit lights of the same color.

In some embodiments, the display 102 is an OLED display, and the light emitting layer 214 includes an array of OLEDs 218 corresponding to the array of subpixels 201. The backplane 216 includes a plurality of pixel circuits 228 configured to drive the plurality of OLEDs 218. In this example shown in FIG. 2A, the light emitting layer 214 also includes a black matrix 226 disposed between the OLEDs 218. The black matrix 226, as the borders of the subpixels 201, is configured to block lights coming out from the parts outside the OLEDs 218. In some embodiments, the black matrix 226 may be disposed on top of the TFT backplane 216 and below the light emitting layer 214.

Each subpixel 201 may include an OLED 218, such as a top emitting OLED, and a pixel circuit 228 for driving the OLED. Each OLED 218 can emit a light in a predetermined brightness and color, such as but not limited to, red, green, blue, yellow, cyan, magenta, or white. For discussion purposes, FIG. 2A shows the display panel 210 includes the OLEDs 218 in three different colors, and A, B, and C in FIG. 2A denote OLEDs in three different colors, such as but not limited to, red, green, blue, yellow, cyan, magenta, or white. In some embodiments, the display panel 210 includes the OLEDs in four different colors, such as but not limited to, red, green, blue, yellow, cyan, magenta, or white. Each OLED 218 may be formed by a sandwich structure of an anode, an organic light-emitting material layer, and a cathode, as known in the art. Depending on the characteristics (e.g., material, structure, etc.) of the organic light-emitting material layer of the respective OLEDs 218, the subpixel 201 may present a distinct color and brightness.

The pixel circuits 228 may be individually addressed by the control signals 108 from the control logic 104, and are configured to drive the corresponding subpixels 201, by controlling the light emitting from the respective OLEDs 218, according to the control signals 108. Each pixel circuit 228 may include one or more thin film transistors (TFTs), one or more storage capacitors, or may include a compensation circuit with more transistors and/or capacitors for brightness uniformity. In some embodiments, the pixel circuit 228 may be in a 2T1C configuration (i.e., including a switching transistor, a driving transistor, and a storage capacitor) or may include a compensation circuit with more transistors and/or capacitors for brightness uniformity, such as in a 7T1C, 5T1C, 5T2C, or 6T1C configuration.

In some embodiments, the backplane 216 is a low temperature polycrystalline silicon (LTPS) backplane, and the pixel circuits 228 include LTPS TFTs. In some embodiments, the backplane 216 is an indium gallium zinc oxide (IGZO) backplane, and the pixel circuits 228 include IGZO TFTs. In some embodiments, the backplane 216 is a low temperature polycrystalline oxide (LTPO) backplane, and the pixel circuits 228 include both LTPS TFTs and IGZO TFTs.

The backplane 216 includes a gate driving circuit 202 and a source driving circuit 204. It is to be appreciated that in some embodiments, the gate driving circuit 202 and the source driving circuit 204 may not be on-panel driving circuits, i.e., not parts of the display panel, but instead are operatively coupled to the display panel. The gate driving circuit 202 in this embodiment is operatively coupled to the active region 200 via a plurality of gate lines (a.k. a. scan lines) and configured to scan the plurality of subpixels 201 based on at least some of the control signals 108. For example, the gate driving circuit 202 applies a plurality of scan signals, which are generated based on the control signals 108 from the control logic 104, to the plurality of gate lines for scanning the plurality of subpixels 201 in a gate scanning order. A scan signal is applied to the gate electrode of a switching transistor of each pixel circuit 228 during the scan period to turn on the switching transistor, so that the data signal for the corresponding subpixel 201 can be written by the source driving circuit 204. It is to be appreciated that although one gate driving circuit 202 is illustrated in FIG. 2B, in some embodiments, multiple gate driving circuits may work in conjunction with each other to scan the subpixels 201.

The source driving circuit 204 in this embodiment is operatively coupled to the active region 200 via a plurality of source lines (a.k. a. data lines) and configured to write display data 106 in a frame to the plurality of subpixels 201 based on at least some of control signals 108. For example, the source driving circuit 204 may simultaneously apply a plurality of data signals to the plurality of source lines for the subpixels 201. That is, the source driving circuit 204 may include one or more shift registers, digital-analog converters (DAC), multiplexers (MUX), and arithmetic circuit for controlling a timing of application of voltage to the source electrode of the switching transistor of each pixel circuit 228 (i.e., during the scan period in each frame) and a magnitude of the applied voltage according to gradations of display data 106. It is to be appreciated that although one source driving circuit 204 is illustrated in FIG. 2A, in some embodiments, multiple source driving circuits may work in conjunction with each other to apply the data signals to the source lines for the subpixels 201.

Additionally or optionally, in some embodiments, the backplane 216 may include a light emitting driving circuit 206, when each subpixel 201 is a light emitting element, such as an OLED. The light emitting driving circuit 206 may be operatively coupled to the active region 200 and configured to cause each subpixel 201 to emit light in each frame based on at least some of control signals 108. For example, the light emitting driving circuit 206 may receive part of control signals 108 including clock signals and enable signals (e.g., start emission STE signals) and generate a set of light emitting signals. The light emitting driving circuit 206 may include one or more shift registers. It is to be appreciated that although one light emitting driving circuit 206 is illustrated in FIG. 2B, in some embodiments, multiple light emitting driving circuits may work in conjunction with each other.

FIG. 2C illustrates an x-y sectional view of the display 102 shown in FIG. 2A including an array of pixels 250 arranged in M rows and N columns. As shown in FIG. 2C, in this embodiment, the plurality of subpixels 201 correspond to an array of pixels 250 arranged in M rows and N columns. The number of the subpixels 201 may be k times of the number of the pixels 250. That is, k subpixels 201 may constitute one pixel 250, and each pixel 250 may consist of k subpixels 201. k may be any positive integer larger than 1. In some embodiments, k may be 2, 3, or 4. It is to be appreciated that in some embodiments, k may be a positive fraction. That is, the number of subpixels 201 may not be an integer multiple of the number of pixels 250. In some embodiments, each row of pixels 250 may include N pixels arranged in the row/horizontal direction (but are not necessarily in a straight line), which include kN subpixels 201. Similarly, in some embodiments, each column of pixels 250 may include M pixels 250 arranged in the column/vertical direction (but are not necessarily in a straight line), which include M subpixels 201. It is to be appreciated that the k subpixels 201 of each pixel 250 (and the kN subpixels 201 in each row of pixels 250 and the M subpixels 201 in each column of pixels 250) may not be physically aligned. In other words, the centers of the k subpixels 201 of each pixel 250 (and the kN subpixels in each row of pixels 250 and the M subpixels 201 in each column of pixels 250) may not be in a straight line in the row/horizontal direction and/or in a straight line in the column/vertical direction. It is also to be appreciated that, the colors, sizes, and/or shapes of the k subpixels 201 of each pixel may not be the same as well.

In some embodiments, the display 102 (and the display panel 210 thereof) has a resolution of N×M, which corresponds to the array of pixels 250 arranged in the M rows and N columns. That is, the display 102 can be characterized by its display resolution, which is the number of distinct pixels 250 in each dimension that can be displayed. For example, for an HD display with a resolution of 1080×1920, the corresponding array of pixels 250 is arranged in 1920 rows and 1080 columns. In this embodiment, referring to FIG. 2A and FIG. 2C, the display data 106 is provided by the processor 114 in display frames. For each frame, the display data 106 includes M×N pieces of pixel data, and each piece of pixel data corresponds to one pixel 250 of the array of pixels 250. Each pixel 250 may be considered as a sample of an original image represented by a piece of pixel data having multiple components, such as multiple color components or a luminance and multiple chrominance components. In some embodiments, each piece of pixel data includes a first component representing a first color, a second component representing a second color, and a third component representing a third color. The first, second, and third colors may be three primary colors (i.e., red, green, and blue) so that each pixel can present a full color. That is, the display data 106 may be programmed at the pixel level. In some embodiments, three subpixels 201 may constitute one pixel 250, i.e., k is 3. In these embodiments, each of the three components of a piece of pixel data may be used to render one of the three subpixels of the respective pixel.

In some display systems, such as the example illustrated in FIG. 2C, X gate lines (G1, G2, . . . , Gx) and Y source lines (S1, S2, . . . , Sy) are provided for the array of pixels 250 arranged in M rows and N columns. X may be any positive integer equal to or larger than M, and Y may be any positive integer equal to or larger than N. In the present disclosure, X and Y may be determined according to different distributive-driving schemes of the display panel 210.

FIG. 3 is a block diagram illustrating one example of control logic 104 shown in FIG. 1 in accordance with an embodiment. In this embodiment, the control logic 104 is an IC (but may alternatively include a state machine made of discrete logic and other components), which provides an interface function between the processor 114 or the memory 116 and display 102. The control logic 104 may provide various control signals 108 with suitable voltage, current, timing, and de-multiplexing, to cause the display 102 to show the desired text or image. The control logic 104 may be an application-specific microcontroller and may include storage units such as RAM, flash memory, EEPROM, and/or ROM, which may store, for example, firmware and display fonts. In this embodiment, the control logic 104 includes a control signal generating module 302, a data interface 304, and a data converting module 306. The data interface 304 may be any display data interface, such as but not limited to, display serial interface (DSI), display pixel interface (DPI), and display bus interface (DBI) by the Mobile Industry Processor Interface (MIPI) Alliance, unified display interface (UDI), digital visual interface (DVI), high-definition multimedia interface (HDMI), and DisplayPort (DP). The data interface 304 is configured to receive the display data 106 in multiple frames and any other control instructions 118 or test signals. The display data 106 may be received in consecutive frames at any frame rates, such as 30, 60, 72, 120, or 240 frames per second (fps). The received display data 106 is forwarded by data interface 304 to control the signal generating module 302 and the data converting module 306.

In this embodiment, the control signal generating module 302 provides the control signals 108 to the gate driving circuit 202, the source driving circuit 204, and the light emitting driving circuit 206 to drive the subpixels in the active region 200. The control signal generating module 302 may include a timing controller 308 and a clock generator 310. The timing controller 308 may provide a variety of enable signals to the gate driving circuit 202, the source driving circuit 204, and the light emitting driving circuit 206, respectively. The clock generator 310 may provide a variety of clock signals to the gate driving circuit 202, the source driving circuit 204, and the light emitting driving circuit 206, respectively.

As described above, the display data 106 may be programmed at the pixel level. In each frame, the display data 106 may include M×N pieces of pixel data corresponding to the array of pixels arranged in the M rows and N columns. Because of the distributive-driving of display panel disclosed herein, the number of the source lines is no longer the same as the number of the columns of pixels multiplied by the ratio k, i.e., the number of data channels (kN). Thus, in some embodiments, the display data 106 may be converted into the display data 316 to accommodate the source line and gate line arrangement due to the specific distributive-driving scheme. In this embodiment, the data converting module 306 provides converted display data 316 to the source driving circuit 204 based on the source line and gate line arrangement on the display panel 210. In some embodiments, the timing of each data signal may be re-arranged according to the gate scanning order as well.

In this embodiment, the data converting module 306 includes a storing unit 312 and a data reconstructing unit 314. The storing unit 312 is configured to receive the display data 106 (original display data) and store the display data 106 in each frame because the conversion of display data 106 may be performed at the frame level. The storing unit 312 may be data latches or line buffers that temporarily store the display data 106 forwarded by the data interface 304. The data reconstructing unit 314 is operatively coupled to the storing unit 312 and configured to reconstruct, in each frame, the display data 106 into corresponding converted display data 316 based on the source line and gate line arrangement on the display panel 210. The data reconstructing unit 314 of the data converting module 306 may convert the display data 106 into converted display data 316 based on the number of source lines according to the distributive-driving scheme. For example, any suitable sampling algorithms may be used by the data reconstructing unit 314 to obtain converted display data 316 suitable for the designed source lines in the display panel 210. It is to be appreciated that in some embodiments, the data converting module 306 may not be included in the control logic 104. Instead, the processor 114 may adjust the timing of the display data 106 to accommodate the source line and gate line arrangement in the display panel 210.

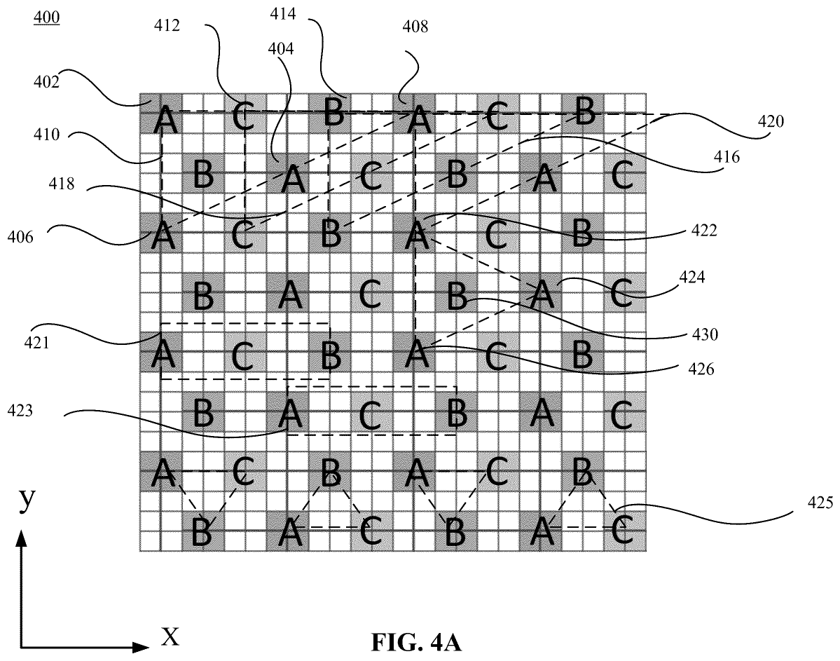

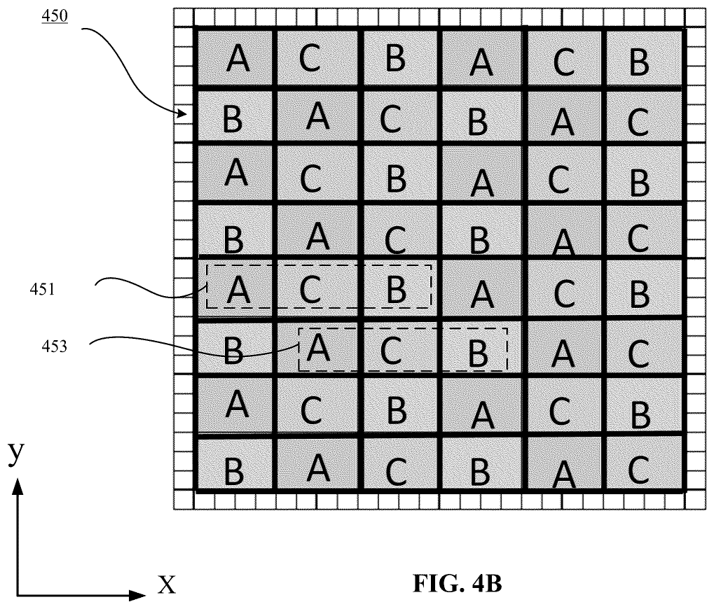

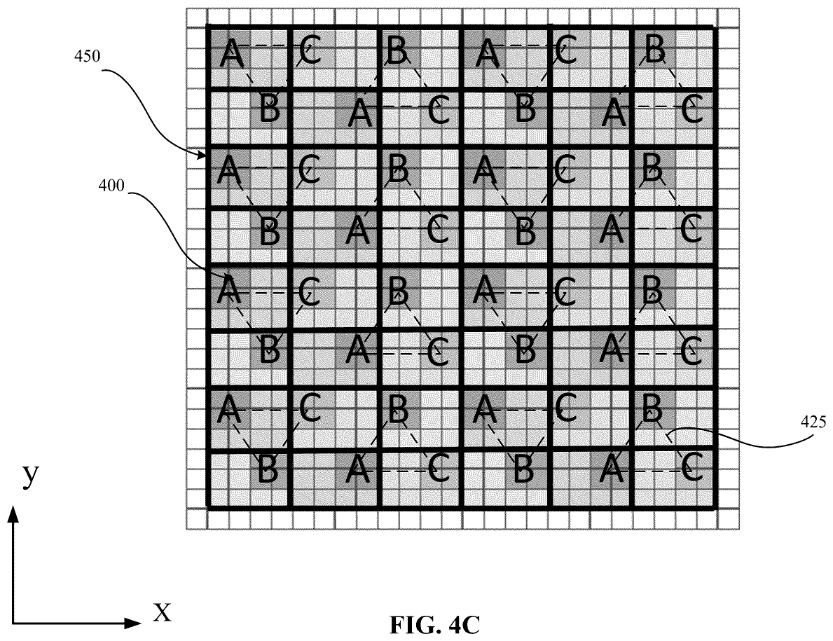

FIG. 4A illustrates a subpixel arrangement of a display in accordance with an embodiment. FIG. 4A may be, for example, a plan-view (e.g., an x-y sectional view) of the display 102, and depicts one example of subpixel arrangements of the display 102. The display 102 includes an array 400 of subpixels in three different colors, A, B, and C. A, B, and C in FIG. 4A denote three different colors, such as but not limited to, red, green, blue, yellow, cyan, magenta, or white. For discussion purposes, each subpixel in FIG. 4A is shown as a grey square having a size of 2 units (indicated by the grid) by 2 units (indicated by the grid). It is to be appreciated that the shape of each subpixel is not limited and may include, for example, circle, triangle, square, rectangle, pentagon, hexagon, heptagon, octagon, or any other suitable regular or irregular shape. The array 400 of subpixels may have the same shape or different shapes in various examples. The size of each subpixel may be the same or different in various examples.

As shown in FIG. 4A, subpixels A, subpixels B, and subpixels C are alternatively arranged in every three adjacent columns of the array 400. For example, the first column from the left of the array 400 includes only subpixels A, the second column of the array 400 includes only subpixels B, and the third column of the array 400 includes only subpixels C. The same pattern is repeated for the next three adjacent columns of the array 400, i.e., columns 4-6, and goes on and on. In other words, all subpixels A are arranged in columns 3n+1, all subpixels B are arranged in columns 3n+2, and all subpixels C are arranged in columns 3n+3 (n=0, 1, 2, 3, . . . ).

Further, in the array 400, every two adjacent columns of subpixels are staggered with one another. That is, subpixels in every two adjacent columns are not aligned with each other in the horizontal axis (directions of rows of the array 400, e.g., an x-axis direction), but instead, are shifted by a distance in the vertical axis (directions of columns of the array 400, e.g., a y-axis). For example, in the array 400, subpixels B in the second column are not aligned with subpixels A in the first column, but instead, are offset from the subpixels A in the first column by a distance (will be described below in detail) toward the bottom. Similarly, subpixels C in the third column are offset from the subpixels B in the second column by the same distance toward the top. The same pattern is repeated for every two adjacent columns of the array 400. As shown in FIG. 4A, subpixels in odd columns (e.g., columns 1, 3, 5, . . . ) are aligned with one another in the horizontal axis, and subpixels in even columns (e.g., columns 2, 4, 6, . . . ) are aligned with one another in the horizontal axis. It is understood that even if two subpixels have different sizes and/or shapes, they are considered as being “aligned” if the geometric centers of the two subpixels are aligned vertically or horizontally.

The display 102 has a delta arrangement of subpixels. In the array 400, in each row, the subpixels A, B, and C are arranged as repeating sequences of A-C-B subpixels. The sequences of A-C-B subpixels in any two adjacent rows are staggered with one another in both the vertical axis (e.g., the y-axis) and the horizontal axis (e.g., the x-axis). For example, as shown in FIG. 4A, two adjacent sequences of A-C-B subpixels in any two adjacent rows are offset by 3 units (indicated by the grid) in the vertical axis (e.g., the y-axis) and 6 units (indicated by the grid) in the horizontal axis (e.g., the x-axis), such as two sequences 421 and 423 of A-C-B subpixels. The delta arrangement of subpixels shown in FIG. 4A can also be described as an arrangement of groups of three subpixels A, B, and C. Three subpixels A, B, and C in each group are arranged in a “triangle” pixel 425 (indicated by the dashed outlines, hence the name “delta”). Any two adjacent groups of three subpixels A, B, and C (or any two adjacent pixels 425) in the row direction are inverted triangles with respect to one another. The delta configuration enables compact subpixel placement and improved uniformity of color mixing across the display panel, while also reducing visual artifacts as compared to strictly rectangular or striped arrangements.

It is noted that the “unit” referred to herein in the present disclosure is not limited by any actual values (e.g., 1 nm, 1 μm, 1 mm, etc.). For example, the array 400 in FIG. 4A has a size of 24 units by 24 units. Depending on the actual size of the array 400 in various examples in practice, each unit may represent different values. The “unit” referred to in the present disclosure, however, can be used for representing relative values between different distances or offsets. For example, “two adjacent sequences of A-C-B subpixels in any two adjacent rows are offset by 3 units in the vertical axis and 6 units in the horizontal axis” can be interpreted as the ratio of vertical offset and horizontal offset between adjacent sequences of A-C-B subpixels is ½.

The relative distances between two subpixels in the same color (e.g., A-A, B-B, or C-C) and two subpixels in different colors (e.g., A-B, B-C, C-A) are now discussed with respect to FIG. 4A. Taking subpixels A for example (and the same can be applied to subpixels B and subpixels C), two subpixels A 402, 404 are in the adjacent columns (columns 1 and 4) and adjacent rows (rows 1 and 2) in which subpixels in this color A are arranged (no subpixels A are arranged in columns 2 and 3). As shown in FIG. 4A, the subpixel A 402 and the subpixel A 404 are offset by 3 units (indicated by the grid) in the vertical axis (e.g., the y-axis) and 6 units (indicated by the grid) in the horizontal axis (e.g., the x-axis). The distance between the subpixel A 402 and the subpixel A 404 is thus about 6.7 units according to the Pythagorean theorem. It is understood that the distance and/or offset between two subpixels is calculated based on the geometric centers of the two subpixels, regardless of the size/or shape thereof. For discussion purposes, FIG. 4A depicts each subpixel as having a square shape of 2 units by 2 units (indicated by the grid).

A subpixel A 406 is another subpixel with the same color as the subpixel A 402, and that is geometrically close to subpixel A 402. The subpixel A 402 and subpixel A 406 are in the same column and have the minimum distance among all subpixels A in that column. As shown in FIG. 4A, the subpixel A 402 and the subpixel A 406 are offset by 6 units in the vertical axis and 0 unit in the horizontal axis (i.e., they are in the same column). In other words, adjacent subpixels in the same column are spaced apart by 6 units from one another. The distance between the subpixel A 402 and the subpixel A 406 is 6 units. A subpixel A 408 is still another subpixel with the same color as the subpixel A 402, and that is geometrically close to the subpixel A 402. The subpixel A 402 and the subpixel A 408 are in the same row and have the minimum distance among all subpixels A in that row. As shown in FIG. 4A, the subpixel A 402 and the subpixel A 408 are offset by 12 units in the horizontal axis and 0 unit in the vertical axis (i.e., they are in the same row). In other words, adjacent subpixels in the same color in the same row are spaced apart by 12 units from one another. The distance between the subpixel A 402 and the subpixel A 408 is 12 units.

Accordingly, in the array 400 of subpixels shown in FIG. 4A, the minimum distance between any two of the subpixels in the same color (e.g., A-A, B-B, or C-C) is thus 6 units (e.g., the distance between the subpixel A 402 and the subpixel A 406). In other words, according to the subpixel arrangement shown in FIG. 4A, two subpixels in the adjacent rows but in the same column, in which subpixels in their color are arranged, have the minimum distance between any two subpixels in the same color. Those two subpixels are offset by 6 units in the vertical axis and 0 unit in the horizontal axis (i.e., they are in the same column). As discussed above, the “unit” referred to in the present disclosure can be used for representing relative values between different distances or offsets. For example, “two subpixels are offset by 3 units in the vertical axis and 6 units in the horizontal axis” can be interpreted as the ratio of vertical offset and horizontal offset between two subpixels is ½. Similarly, although the distance of 6.7 units between subpixel the A 402 and the subpixel 404 is not limited to any actual value of distance, it can be compared with the distance of 6 units between the subpixel A 402 and the subpixel 406, e.g., the ratio of the two distances is 6.7/6.

As shown in FIG. 4A, the four subpixels A 402, 404, 406, 408 form a repeating group 410 for subpixels in color A. The repeating group A 410 is tiled across the display panel in a regular pattern. That is, the repeating group A 410 repeats itself in the horizontal axis with a pitch of 12 units and in the vertical axis with a pitch of 6 units. Like the repeating group A 410, repeating group B 416, and repeating group C 418 can be formed by subpixels B and subpixels C, respectively, in the same manner. Each of the repeating group B 416 and repeating group C 418 repeats itself in the horizontal axis with a pitch of 12 units and in the vertical axis with a pitch of 6 units.

As shown in FIG. 4A, subpixel C 412 and subpixel B 414 between the two subpixels A 402, 408 in the same row evenly divide the distance of 12 units between the two subpixels A 402, 408. Thus, the distance (i.e., horizontal offset) between the subpixel A 402 and the subpixel C 412 is 4 units, and the distance (i.e., horizontal offset) between the subpixel A 402 and the subpixel B 414 is 8 units. In other words, adjacent subpixels in the same column are spaced apart by 4 units from one another, regardless of their colors. Thus, another way to look at the repeating groups in different colors is that the repeating group in the first color and each of the other two repeating groups in the second and third colors are offset by 4 units in the horizontal axis and 0 unit in the vertical axis, respectively, and that the two repeating groups in the second and third colors are offset from the repeating group in the first color in opposite directions of the horizontal axis. As shown in FIG. 4A, from the repeating group B 416's perspective, the repeating group C 418 is offset by 4 in the left direction of the horizontal axis, while the repeating group A 420 is offset by 4 in the right direction of the horizontal axis.

As shown in FIG. 4A, for example, two adjacent subpixels A 422, 426 in the same column and another subpixel A 424 form an isosceles triangle, within which a subpixel B 430 is disposed. The distance between the subpixel B 430 and the subpixel A 424 is 4 units as described above. The distance between subpixel B 430 and each of the subpixels A 422, 426 is thus about 3.6 units according to the Pythagorean theorem, which is less than 4 units. Accordingly, the minimum distance between any two subpixels in the different colors (e.g., A-B, B-C, or C-A) is thus 3.6 units. In other words, according to the disclosed subpixel arrangement shown in FIG. 4A, two adjacent subpixels that are staggered in both the horizontal direction and the vertical direction have the minimum distance between any two subpixels in the different colors. In other words, two adjacent subpixels that are not aligned in the same row or the same column have the minimum distance between any two subpixels in different colors. As discussed above, the minimum distance between any two subpixels in the same color is 6 units.

In this embodiment, each of the subpixels of the array 400 includes an OLED. Thus, the array 400 of subpixels can be considered as an array of OLEDs as well. It is understood that the subpixels are not limited to OLEDs, and may be, for example, LEDs of a billboard display with LEDs or any other suitable display devices as known in the art. Although subpixels/OLEDs in three colors (A, B, and C) are described in FIG. 4A, subpixels/OLEDs in four or more colors may be included in other examples.

FIG. 4B depicts a driving element arrangement of a display in accordance with an embodiment. As discussed above, each subpixel (e.g., an OLED) is driven by a corresponding driving element in the backplane 216 of the display panel 210. That is, the display panel 210 includes an array 450 of driving elements for driving the array 400 of subpixels. The arrangement of driving elements does not necessarily have to be the same as that of the subpixels. FIG. 4B may be, for example, a plan-view (e.g., an x-y sectional view) of the display 102, and depicts one example of driving element arrangement of the display 102 corresponding to the subpixel arrangement shown in FIG. 4A. Each of the rectangles in FIG. 4B represents a driving element (or a region disposed with a driving element) that includes one or more TFTs, such as one or more LTPS TFTs, one or more IGZO TFTs, etc. A, B, C in FIG. 4B denote the driving elements configured to drive subpixels A, B, and C, respectively.

As shown in FIG. 4B, driving elements in the array 450 are in line with one another in both the horizontal axis and vertical axis. That is, the driving elements in each row of the array 450 of driving elements are aligned, and the driving elements in each column of the array 450 of driving elements are aligned as well. Further, in the array 450, in each row, the driving elements are arranged as repeating sequences of A-C-B driving elements, similar to the repeating sequences of A-C-B subpixels shown in FIG. 4A. The sequences of A-C-B driving elements in any two adjacent rows are staggered with one another in both the vertical axis (e.g., the y-axis) and the horizontal axis (e.g., the x-axis). For example, the array 450 in FIG. 4B has a size of 24 units by 24 units (indicated by the grid), where the outermost columns on the left and right sides, and the outermost rows on the top and bottom, are reserved as coordinate markers for indicating the position, offset, and size of the driving elements. Each driving element (or a region disposed with a driving element) is denoted as a rectangle having a size of 4 units by 3 units, and two adjacent sequences of A-C-B driving elements in any two adjacent rows are offset by 3 units in the vertical axis (e.g., the y-axis) and 4 units in the horizontal axis, such as two sequences 451 and 453 of A-C-B driving elements.

For example, as shown in FIG. 4B, each of the (3n+1)-th driving elements in odd rows (n=0, 1, 2, 3, . . . ) and each of the (3n+2)-th driving elements in even rows (n=0, 1, 2, 3, . . . ) are configured to drive subpixels A. Each of the (3n+2)-th driving elements in odd rows (n=0, 1, 2, 3, . . . ) and each of the (3n+3)-th driving elements in even rows (n=0, 1, 2, 3, . . . ) are configured to drive subpixels C. Each of the (3n+3)-th driving elements in odd rows (n=0, 1, 2, 3, . . . ) and each of the (3n+1)-th driving elements in even rows, n=0, 1, 2, 3, . . . ) are configured to drive the subpixels B. The driving elements in each row of the array 450 are configured to drive a same number of subpixels A, B, C. In the example of FIG. 4C, in each row of the array 450, ⅓ of the driving elements are configured to drive subpixels A, ⅓ of the driving elements are configured to drive subpixels B, and ⅓ of the driving elements are configured to drive subpixels C.

Further, in the first column of the array 450 from the left, each odd driving element is configured to drive the subpixel A, and each even driving element is configured to drive the subpixel B. That is, the driving elements in the first column of the array 450 are configured to drive alternated subpixels A and subpixels B. In the second column of the array 450, each odd driving element is configured to drive the subpixel C, and each even driving element is configured to drive the subpixel A. That is, the driving elements in the second column of the array 450 are configured to drive alternated subpixels C and subpixels A. In the third column of the array 450, each odd driving element is configured to drive the subpixel B, and each even driving element is configured to drive the subpixel C. That is, the driving elements in the second column of the array 450 are configured to drive alternated subpixels B and subpixels C. The same pattern described above is repeated for the rest of the driving elements in the array 450.

Further, driving elements in each column of the array 450 are configured to drive a same number of subpixels of two different colors. In the example of FIG. 4B, in each (3n+1)-th (n=0, 1, 2, 3, . . . ) column of the array 450, ½ of the driving elements are configured to drive the subpixels A, and ½ of the driving elements are configured to drive the subpixels B. Similarly, in each (3n+2)-th (n=0, 1, 2, 3, . . . ) column of the array 450, 1/2 of the driving elements are configured to drive the subpixels C, and ½ of the driving elements are configured to drive the subpixels A. Similarly, in each (3n+3)-th (n=0, 1, 2, 3, . . . ) column of the array 450, ½ of the driving elements are configured to drive the subpixels B, and ½ of the driving elements are configured to drive the subpixels C.

FIG. 4C illustrates an example of a display including an example of an array of subpixels aligned with an example of an array of driving elements in accordance with an embodiment. FIG. 4C may be, for example, a plan-view (e.g., an x-y sectional view) of the display 102 including the array 400 of subpixels shown in FIG. 4A aligned and superimposed with the array 450 of driving elements shown in FIG. 4B. As shown in FIG. 4C, each of the array 400 and the array 450 has a size of 24 units by 24 units (indicated by the grid), where the outermost columns on the left and right sides, and the outermost rows on the top and bottom, are reserved as coordinate markers for indicating the position, offset, and size of the driving elements and subpixels.

In the example of FIG. 4C, the array 400 of subpixels corresponds to an array of pixels 425 arranged in M rows and N columns. The number of the subpixels is k times (k=3) of the number of the pixels 425. That is, the number of the pixels 425 is M*N, and the number of the subpixels is 3*M*N. The array 400 of subpixels may be arranged in 2*M rows. That is, the number (2*M) of the rows of subpixels is twice the number (M) of the rows of pixels 425. The array 400 of subpixels may be arranged in (k/2)*N columns (e.g., k=3). That is, the number ((k/2)*N) of the columns of subpixels is k/2 times of the number (N) of the columns of pixels 425 (k=3). In the example of FIG. 4C, the array 450 of driving elements corresponds to the array 400 of subpixels, and is also arranged in 2*M rows and (3/2)*N columns. For discussion purposes, FIG. 4C shows the array 400 of subpixels is arranged in 8 rows and 6 columns, corresponding to the array of pixels 425 arranged in 4 (i.e., M=4) rows and 4 (i.e., N=4) columns. The array 450 of driving elements is arranged in 8 rows and 6 columns, corresponding to the array 400 of subpixels is arranged in 8 rows and 6 columns.

Referring to FIGS. 4A-4C, when the array 400 of subpixels shown in FIG. 4A are aligned and superimposed with the array 450 of driving elements shown in FIG. 4B, each subpixel of a predetermined color is aligned with a corresponding driving element configured to drive that color subpixel, and is not aligned with driving elements configured to drive subpixels of other colors. For example, each subpixel A is aligned with the driving element configured to drive subpixels A and is not aligned with the driving elements configured to drive subpixels B or C, each subpixel B is aligned with the driving element configured to drive subpixels B and is not aligned with the driving elements configured to drive subpixels A or C, and each subpixel C is aligned with the driving element configured to drive subpixels C and is not aligned with the driving elements configured to drive subpixels A or B. This configuration significantly reduces the routing complexity between the subpixels in the array 400 and the corresponding driving elements in the array 450, thereby eliminating the need for additional fan-out routing.

Referring to FIGS. 4A-4C, the subpixels in each row of the array 400 are aligned with the respective corresponding driving elements in the same row of the array 450. For example, the subpixels A in each row from the top of the array 400 are aligned with respective corresponding driving elements A in the same row of the array 450 (e.g., each of the (3n+1)-th driving elements in odd rows, n=0, 1, 2, 3, . . . and each of the (3n+2)-th driving elements in even rows, n=0, 1, 2, 3, . . . ). The subpixels C in each row of the array 400 are aligned with respective corresponding driving elements in the same row of the array 450 (e.g., each of the (3n+2)-th driving elements in odd rows, n=0, 1, 2, 3, . . . and each of the (3n+3)-th driving elements in even rows, n=0, 1, 2, 3, . . . ). The subpixels B in each row of the array 400 are aligned with respective corresponding driving elements in the same row of the array 450 (e.g., each of the (3n+3)-th driving elements in odd rows, n=0, 1, 2, 3, . . . and each of the (3n+1)-th driving elements in even rows, n=0, 1, 2, 3, . . . ).

Further, the driving elements in each column of array 450 are aligned with corresponding subpixels of alternating colors from two adjacent columns of array 400. For example, the subpixels A in the first column from the left of the array 400 are aligned with the respective corresponding driving elements in the first column from the left of the array 450 (e.g., each odd driving element in the first column). The subpixels B in the second column from the left of the array 400 are aligned with the respective corresponding driving elements in the first column from the left of the array 450 (e.g., each even driving element in the first column). That is, the driving elements in the first column from the left of the array 450 are configured to align with alternated subpixels A and subpixels B located in two adjacent columns of the array 400.

The subpixels C in the third column from the left of the array 400 are aligned with the respective corresponding driving elements in the second column from the left of the array 450 (e.g., each odd driving element in the second column). The subpixels A in the fourth column from the left of the array 400 are aligned with the respective corresponding driving elements in the second column from the left of the array 450 (e.g., each even driving element in the second column). That is, the driving elements in the second column from the left of the array 450 are configured to align with alternated subpixels C and subpixels A located in two adjacent columns of the array 400.

The subpixels B in the fifth column from the left of the array 400 are aligned with the respective corresponding driving elements in the third column from the left of the array 450 (e.g., each odd driving element in the third column). The subpixels C in the sixth column from the left of the array 400 are aligned with respective corresponding driving elements in the third column from the left of the array 450 (e.g., each even driving element in the third column). That is, the driving elements in the third column from the left of the array 450 are configured to align with alternated subpixels B and subpixels C located in two adjacent columns of the array 400. The same pattern is repeated for the next three adjacent columns of the array 450, i.e., columns 4-6, and goes on and on.

Further, as shown in FIG. 4C, the subpixels A, B, and C are aligned with corresponding driving elements, with some subpixels aligned to the same portions of their respective driving elements and others aligned to different portions. In some embodiments, the subpixels in each row of the array 400 are aligned to the same portions of respective corresponding driving elements in the same row of the array 450, and the subpixels in two adjacent rows of the array 400 are aligned to different portions of respective corresponding driving elements in two adjacent rows of the array 450. For example, in FIG. 4C, the subpixels in each odd row of the array 400 are aligned to the same upper-left portions of respective corresponding driving elements in the same row of the array 450, and the subpixels in each even row of the array 400 are aligned to the same upper-right portions of respective corresponding driving elements in the same row of the array 450.

Further, the driving elements in each column of array 450 are aligned with corresponding subpixels of alternating colors from two adjacent columns of array 400, at different portions of the respective driving elements. For example, in the first column from the left of the array 450, the subpixels A are aligned to the same upper-left portions of respective corresponding driving elements (e.g., each odd driving element in the first column), and the subpixels B are aligned to the same upper-right portions of the respective corresponding driving elements (e.g., each even driving element in the first column). In the second column from the left of the array 450, the subpixels C are aligned to the same upper-left portions of respective corresponding driving elements (e.g., each odd driving element in the second column), and the subpixels A are aligned to the same upper-right portions of the respective corresponding driving elements (e.g., each even driving element in the second column). In the third column from the left of the array 450, the subpixels B are aligned to the same upper-left portions of respective corresponding driving elements (e.g., each odd driving element in the third column), and the subpixels C are aligned to the same upper-right portions of the respective corresponding driving elements (e.g., each even driving element in the third column). The same pattern is repeated for the next three adjacent columns of the array 450, i.e., columns 4-6, and goes on and on.

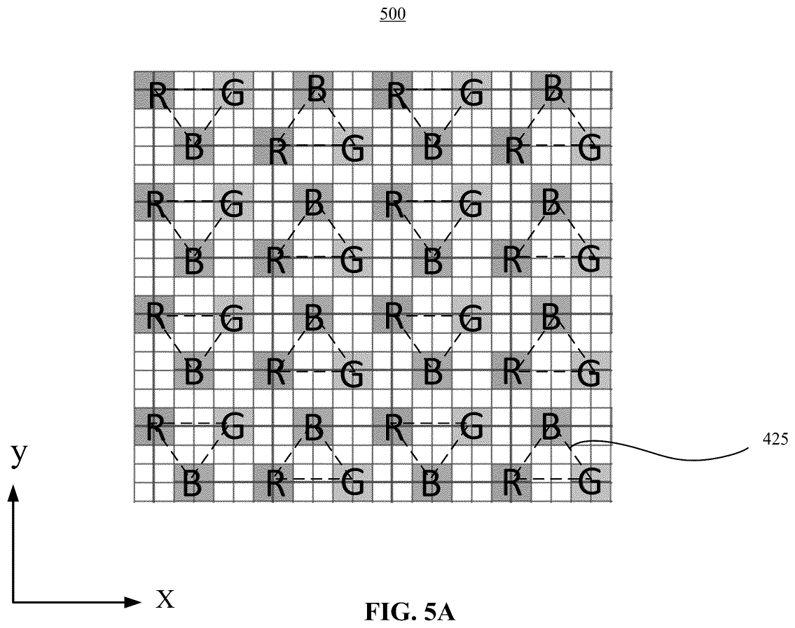

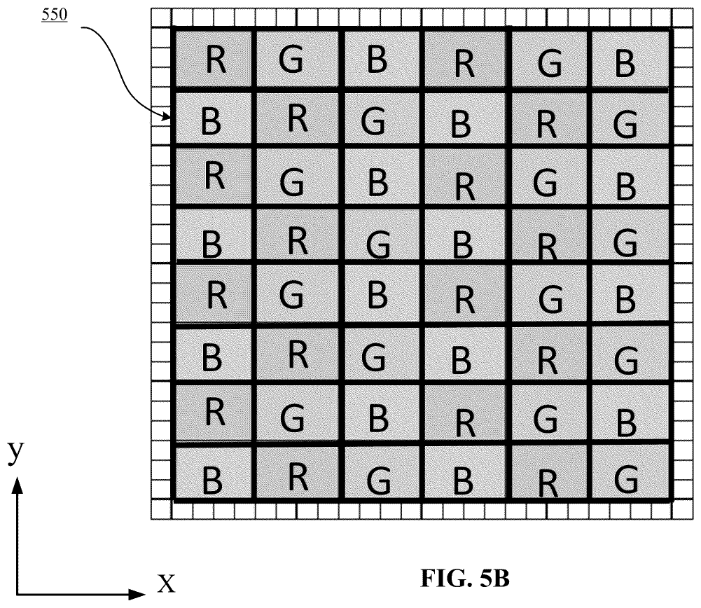

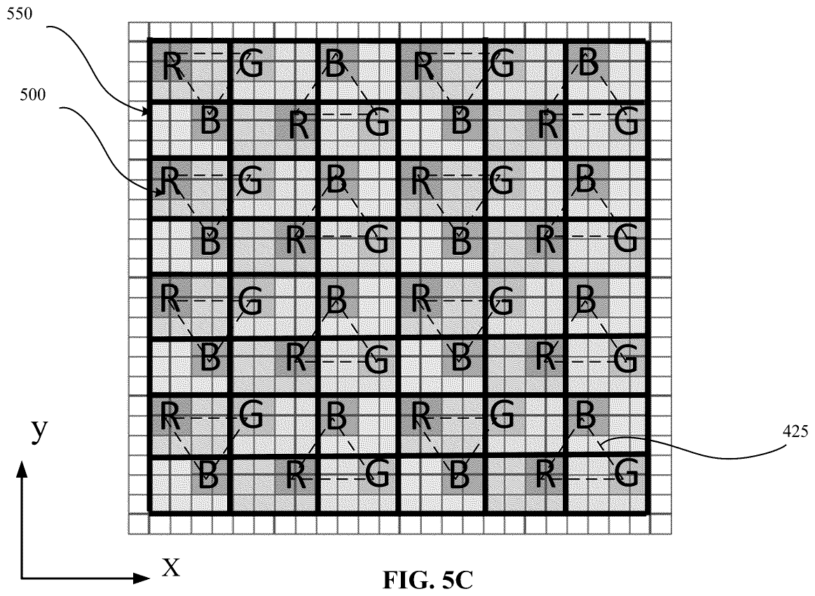

In some embodiments, in each subpixel of the array 400, each OLED emits one of the red, green, and blue lights, and the subpixels A, B, C correspond to red subpixels, blue subpixels, and green subpixels, respectively, as denoted by R, B, and G, respectively. For example, FIG. 5A illustrates an example of an array 500 of subpixels where the subpixels A, B, and C in the display shown in FIG. 4A correspond to subpixels R, B, and G, respectively. In the example shown in FIG. 5A, the array 500 of subpixels are arranged in 6 rows and 8 columns, corresponding to an array of pixels 425 arranged in 4 rows and 4 columns. FIG. 5B illustrates an example of an array 550 of driving elements corresponding to the array of subpixels shown in FIG. 5A. In the example shown in FIG. 5B, the array 550 of driving elements are arranged in 6 rows and 8 columns, corresponding to the array of pixels 425 arranged in 6 rows and 8 columns shown in FIG. 5A. FIG. 5C illustrates an example of a display including the array 500 of subpixels shown in FIG. 5A aligned with the array 550 of driving elements shown in FIG. 5B.

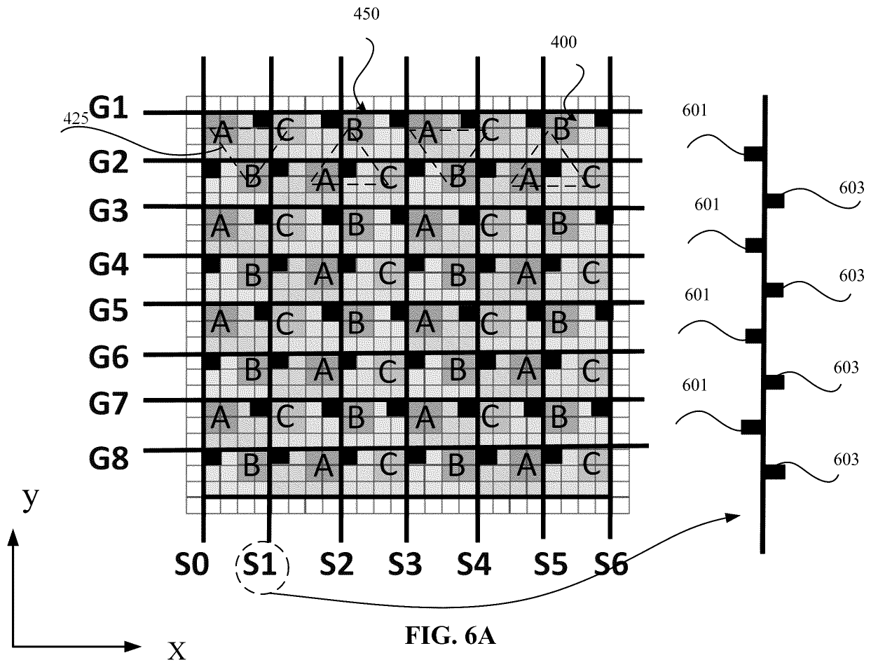

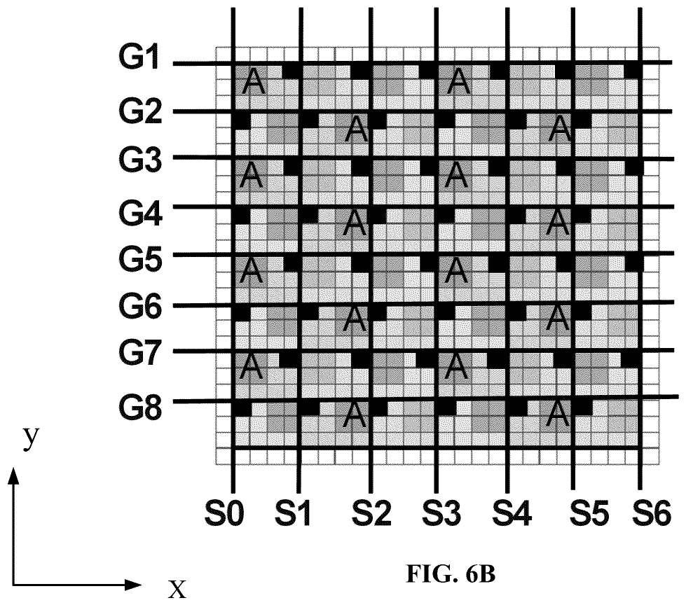

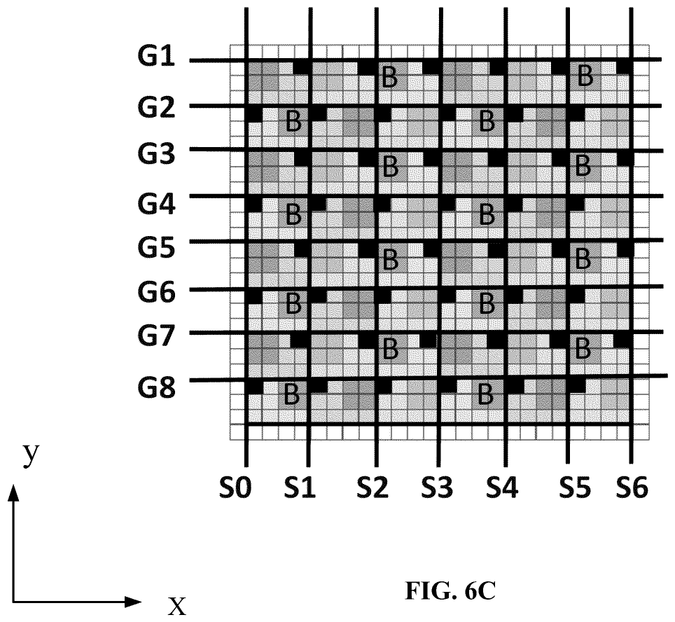

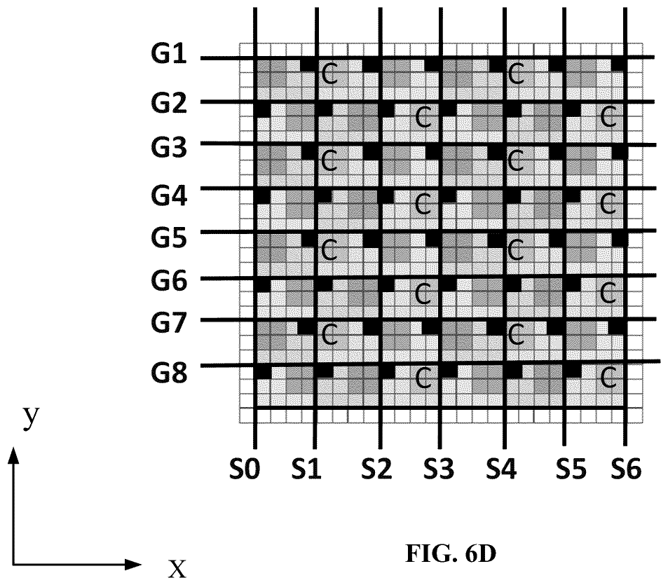

FIG. 6A illustrates an arrangement of gate lines and source lines of driving elements for distributive-driving of subpixels in a display in accordance with an embodiment. FIG. 6A may be, for example, a plan-view (e.g., an x-y sectional view) of the display 102, and depicts one example of an arrangement of gate lines and source lines of driving elements shown in FIG. 4C for distributive-driving of subpixels shown in FIG. 4C. As shown in FIG. 6A, as discussed above, for the array of pixels 425 arranged in M (e.g., M=4) rows and N (e.g., N=4) columns, the array 400 of subpixels are arranged in 2*M rows and (3/2)*N columns, and the array 450 of driving elements that is aligned with the array 400 of subpixels are also arranged in 2*M rows and (3/2)*N columns. For distributive-driving of subpixels in the array 400 of pixels, X gate lines (G1, G2, . . . , Gx) and Y source lines (S1, S2, . . . , Sy) are provided to the display 210.

In the example of FIG. 6A, the driving elements in each of the M rows of the pixels 425 are operatively coupled to two gate lines, and are written with scan signals transmitted via the two gate lines. The driving elements in each row of the 2*M rows of the array 450 is operatively coupled to one gate line, and are scanned by a scan signal transmitted via the gate line. For example, one half (e.g., upper half) of the subpixels in a row of pixels 425 may be scanned via one gate line, and the other half (e.g., lower half) of the subpixels in the same row of pixels may be scanned via another gate line. That is, the number of the gate lines (2*M) is twice the number of the rows of pixels (M), and 2*M (i.e., X=2*M) gate lines (G₁, . . . G_{2M}) are provided to the array of pixels 425.

Further, the source lines are operatively coupled to the columns of driving elements via output pins configured with a “zigzag” arrangement. The output pins positioned in the odd rows and even rows of the array 450 are shifted (or spaced apart) by a predetermined distance (e.g., one driving element) in the vertical direction. As a result, the number of the source lines may be more than k/2 times of the number of the columns of pixels (N). For example, the number of the source lines may be (k/2) times of the number of the columns of pixels (N) plus 1, and (k/2)*N+1 (i.e., Y=(k/2)*N+1, e.g., k=3) source lines (S₁, . . . S_{(k/2)*N+1}) are provided to the array of pixels 425. That is, on average, the driving elements in each of the N columns of the pixels 425 are operatively coupled to (k/2+1/N) source lines, and are written with data signals transmitted via the (k/2+1/N) source lines. For example, a disclosed display panel having 1920×1080 resolution are provided with 1,621 source lines ((3/2)*1080+1) and 3,840 (1920×2) gate lines.

FIG. 6A illustrates a “zigzag” arrangement of output pins 601 and output pins 603 at a source line S1. As shown in FIG. 6A, the output pins 601 and 603 are disposed along the source line S1 at spaced intervals, and each output pin 601 or 603 is configured to provide an electrical connection between the source line S1 and a corresponding driving element. The output pins 601 are positioned at the odd rows in the array 450, and are configured for the driving elements disposed in the odd rows in the array 450. Two adjacent output pins 601 are shifted (or spaced apart) by a predetermined distance (e.g., two driving elements) in the vertical direction. The output pins 603 are positioned at the even rows in the array 450, and are configured for the driving elements disposed in the even rows in the array 450. Two adjacent output pins 603 are shifted (or spaced apart) by a predetermined distance (e.g., two driving elements) in the vertical direction.

The output pin 601 and the adjacent output pin 603 are shifted (or spaced apart) by a predetermined distance (e.g., one driving element) in the vertical direction. The output pins 601 for the driving elements disposed in each odd row of the 2*M rows of the array 450 may extend (e.g., laterally) toward a first direction (e.g., −x-axis direction), and the output pin 603 for the driving elements in each even row of the 2*M rows of the array 450 may extend (e.g., laterally) towards a second different direction (e.g., +x-axis direction).

The source line S1 is operatively coupled to the driving elements disposed in each odd row of the 2*M rows of the array 450 via the output pins 601, and operatively coupled to the driving elements disposed in each even row of the 2*M rows of the array 450 via the output pins 603. Thus, the source line S1 is operatively coupled to the driving elements positioned in two adjacent columns of the array 450, e.g., the driving elements positioned in each odd row and one of the two adjacent columns, and the driving elements positioned in each even row and the other of the two adjacent columns. The second source line S1 to the second-to-last source line S_{Y-1} may have the same configuration, e.g., zigzag output pins. The first source line S0 may only include the output pins 603 for the driving elements in each even row of the 2*M rows of the array 450, and the last source line S_{Y} may only include the output pins 601 for the driving elements in each odd row of the 2*M rows of the array 450. Thus, ((k/2)*N+1) source lines (i.e., Y=(k/2)*N+1) are provided for the array of pixels 425 (e.g., k=3). That is, the number of source lines is k/2 times of the number of the columns of pixels (N) plus 1 (e.g., k=3).

Through configuring the “zigzag” arrangement of the output pins 601 and output pins 603 at the source lines, each of the second source line S1 to the second-to-last source line S_{Y-1} is operatively coupled to the driving elements configured to drive the subpixels of the same color, without being shared by the driving elements configured to drive the subpixels of different colors. In other words, all the driving elements operatively coupled to each of the second source line S1 to the second-to-last source line S_{Y-1} are configured to drive the subpixels of the same color.

As the first source line S0 only includes output pins positioned in even rows, and the last source line S_{Y} only includes output pins positioned in odd rows, each of the first source line S0 and the last source line S_{Y} is also operatively coupled to the driving elements configured to drive the subpixels of the same color. Thus, when displaying pure red or blue images, the high-frequency toggling of the source lines may be significantly suppressed and, accordingly, the power consumption may be significantly reduced. Since the display of typical color images generally involves fewer high-frequency color switching events than the display of pure red or pure blue images, the overall power consumption for color images is closer to that of pure-color images.

In the example in FIG. 6A, eight gate line G1 to G8 and seven source lines S0 to S7 are provided to the array of pixels 425. In particular, the output pins 601 and 603 of the source lines (e.g., S1, S2 . . . S6) for the driving elements positioned in the odd rows (e.g., the 1^{st}, 3^{rd}, 5^{th}, and 7^{th} from the top) and even rows (e.g., the 2^{nd}, 4^{th}, 6^{th}, and 8^{th} from the top) of the array 450 are shifted by one driving element in the vertical direction. The output pins 601 extend (e.g., laterally) toward the left, and the output pin 603 extends (e.g., laterally) towards the right. The source lines S1 and S4 are operatively coupled to the driving elements configured to drive the subpixels A only. The source lines S0, S3, and S6 are operatively coupled to the driving elements configured to drive the subpixels B only. The source lines S2 and S5 are operatively coupled to the driving elements configured to drive the subpixels C only.

FIG. 6B illustrates displaying an image of pure color A by the display 102 in accordance with an embodiment. As shown in FIG. 6B, when displaying an image of pure color A, the source driving circuit 204 may simultaneously apply data signals (e.g., high voltages) to the source lines S1 and S4, and apply other data signals (e.g., low voltages) to the remaining source lines. FIG. 6C illustrates displaying an image of pure color B by the display 102 in accordance with an embodiment. As shown in FIG. 6C, when displaying an image of pure color B, the source driving circuit 204 may simultaneously apply data signals (e.g., high voltages) to the source lines S0, S3, and S6, and apply other data signals (e.g., low voltages) to the remaining source lines.

FIG. 6D illustrates displaying an image of pure color C by the display 102 in accordance with an embodiment. As shown in FIG. 6D, when displaying an image of pure color C, the source driving circuit 204 may simultaneously apply data signals (e.g., high voltages) to the source lines S2 and S5, and apply other data signals (e.g., low voltages) to the remaining source lines. As shown in FIGS. 6B-6D, as each source line is only operatively coupled to the driving elements configured to drive the subpixels of the same color, when displaying pure color images, data signals applied to the corresponding source lines may remain at high voltages, while data signals applied to the other source lines may remain at low voltages. Thus, the high-frequency toggling of the source lines between a high voltage and a low voltage are significantly suppressed, and the power consumption is significantly reduced.

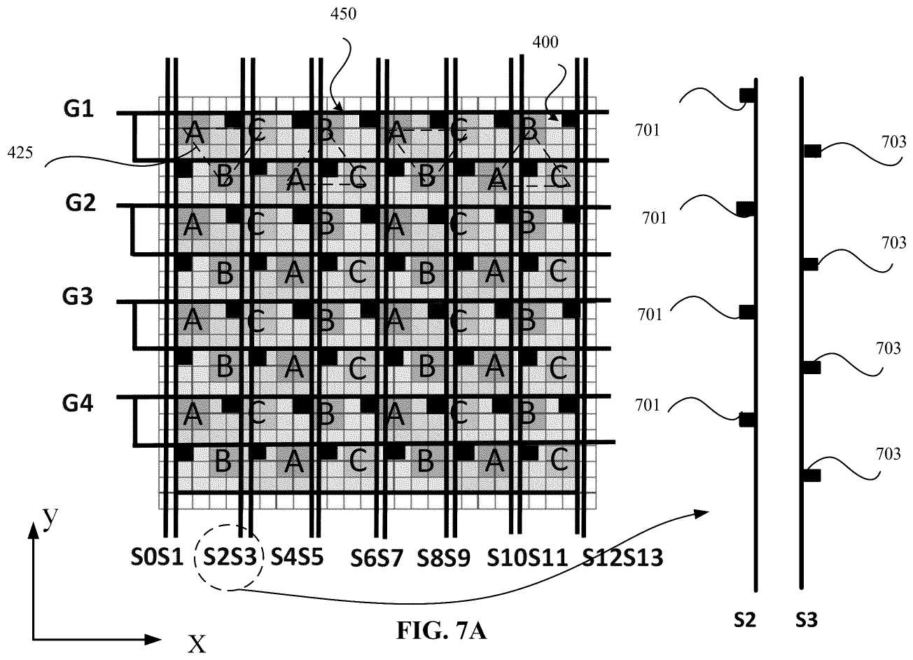

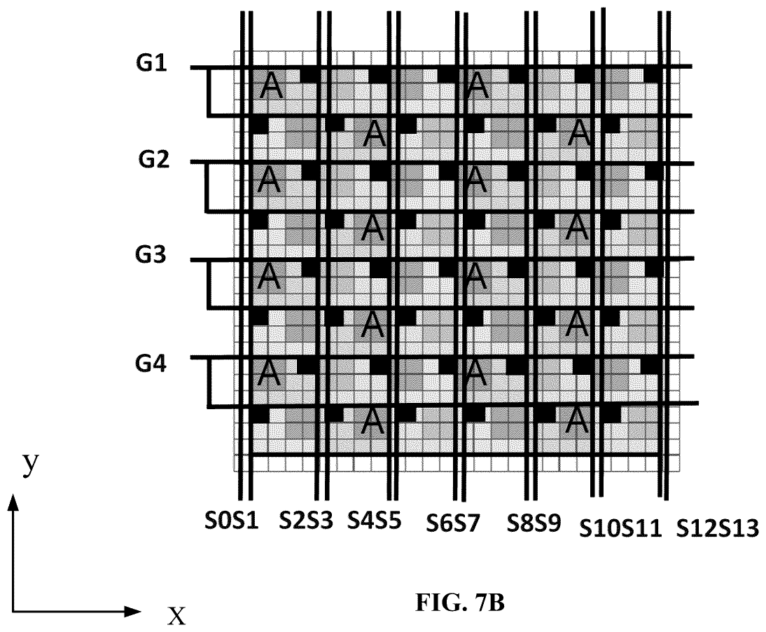

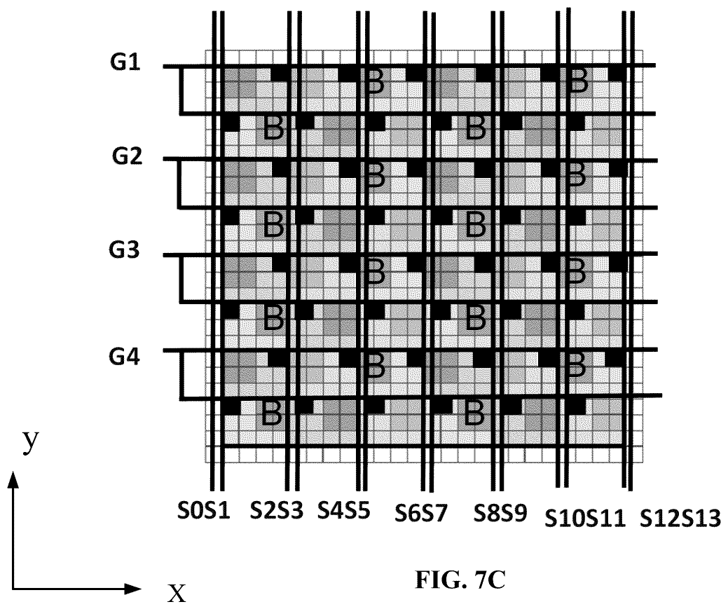

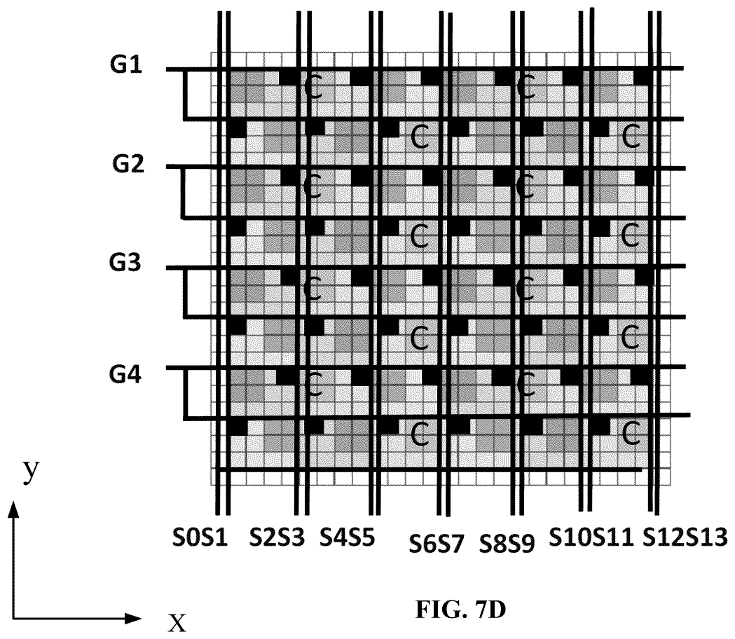

FIG. 7A illustrates an example of an arrangement of gate lines and source lines of driving elements for distributive-driving of subpixels in a display in accordance with an embodiment. FIG. 7A may be, for example, a plan-view (e.g., an x-y sectional view) of the display 102, and depicts one example of an arrangement of gate lines and source lines of driving elements in the example arrangement shown in FIG. 4C for distributive-driving of subpixels in the example arrangement shown in FIG. 4C. Compared to the example of FIG. 6A, in the example of FIG. 7A, the number of gate lines may be reduced to increase the charging time of the source lines by correspondingly increasing the number of source lines. For example, the number of source lines may be doubled to ((k/2)*N+1)×2=k*N+2, while the corresponding number of gate lines can be reduced by half to 2*M/2=M.

Thus, a disclosed display panel having 1920×1080 resolution is provided with 3,242 source lines (3*1080+2) and 1920 gate lines. The total number of source and gate lines in the disclosed display panel 210 is substantially the same as that of a conventional “real-RGB” AMOLED panel shown in FIG. 11C, except for a difference of only two source lines. However, the disclosed arrangement of gate lines and source lines shown in FIG. 7A may significantly reduce the complexity of the metal line layout, and lower the panel power consumption.

As shown in FIG. 7A, the driving elements in each of the M rows of pixels 425 is operatively coupled to one gate line and are scanned by a scan signal transmitted via the gate line. That is, the number of the gate lines (M) is the same as the number of the rows of pixels (M), and M (i.e., X=M) gate lines (G1, . . . G_{M}) are provided for the array of pixels 425. Further, the source lines are operatively coupled to the columns of driving elements. In FIG. 7A, each source line shown in FIG. 6A is replaced by a group of two source lines and thus, the number of the source lines is doubled. For example, the number of the source lines may be k*N+2 (e.g., k=3), i.e., the number of source lines is k times of the number of the columns of pixels (N) plus 2 (i.e., Y=k*N+2, e.g., k=3). That is, ((k/2)*N+1) group of source lines are provided for the array of pixels 425 (k=3), with each group includes two source lines. On average, the driving elements in each of the N columns of the pixels 425 are operatively coupled to (k+2/N) source lines, and are written with data signals transmitted via the (k+2/N) source lines.

In the example of FIG. 7A, a first group in the ((k/2)*N+1) group of source lines includes two adjacent source lines S₀S₁. The output pins at the source line S₁ are positioned in the even rows of the array 450 and extend (e.g., laterally) toward the second direction (e.g., +x-axis direction), and adjacent output pins at the source line S₁ are shifted (or spaced apart) by two driving elements in the vertical direction. The source line S₀ may either be provided without output pins, or provided with output pins that are not connected to any driving element. In some embodiments, the source line S₀ may be omitted. The last group in the ((k/2)*N+1) group of source lines includes two adjacent source lines S_{Y-1}S_{Y} (Y=k*N+2, e.g., k=3). The output pins at the source line S_{Y-1} are positioned in the odd rows of the array 450, and extend (e.g., laterally) toward the first direction (e.g., −x-axis direction), and adjacent output pins at the source line S_{Y-1} are shifted (or spaced apart) by two driving elements in the vertical direction. The source line S_{Y} may either be provided without output pins, or provided with output pins that are not connected to any driving element. In some embodiments, the source line S_{Y} may be omitted.

Each of the second group to the second-to-last group in the ((k/2)*N+1) group of source lines includes two adjacent source lines S₂ₙS₍₂ₙ₊₁₎ (n=1, 2, 3, . . . ). The output pins at the source line S₂ₙ are positioned in the odd rows of the array 450 and extend (e.g., laterally) toward the first direction (e.g., −x-axis direction), and adjacent output pins are shifted (or spaced apart) by two driving elements in the vertical direction. The output pins at the source line S₍₂ₙ₊₁₎ are positioned in the even rows of the array 450 and extend (e.g., laterally) toward the second, different, direction (e.g., +x-axis direction), and adjacent output pins are shifted (or spaced apart) by two driving elements in the vertical direction. Two adjacent output pins of the source line S₂ₙ and the source line S₍₂ₙ₊₁₎ are shifted (or spaced apart) by one driving element in the vertical direction.

FIG. 7A illustrates an arrangement of output pins 701 and output pins 703 at the second group of source lines including a source line S2 and a source line S3. As shown in FIG. 7A, the output pins 701 at the source line S2 are positioned in the odd rows of the array 450 and extend (e.g., laterally) toward the first direction (e.g., −x-axis direction), and adjacent output pins are shifted (or spaced apart) by two driving elements in the vertical direction. The output pins 703 at the source line S3 are positioned in the even rows of the array 450 and extend (e.g., laterally) toward the second direction (e.g., +x-axis direction), and adjacent output pins are shifted (or spaced apart) by two driving elements in the vertical direction. The output pin 701 of the source line S2 and the adjacent output pin 703 of the source line S2 are shifted (or spaced apart) by one driving element in the vertical direction.

In the example of FIG. 7A, each group in the ((k/2)*N+1) group of source lines is operatively coupled to the driving elements configured to drive the subpixels of the same color. Thus, when displaying pure red or blue images, the high-frequency toggling of the source lines may be significantly suppressed and, accordingly, the power consumption may be significantly reduced. Since the display of typical color images generally involves fewer high-frequency color switching events than the display of pure red or pure blue images, the overall power consumption for color images is closer to that of pure-color images.

In the example in FIG. 7A, four gate line G1 to G4 and seven groups of source lines S0S1 to S12S13 are provided to the array of pixels 425. In particular, the output pins 701 of the source lines (e.g., S1, S3, S5, . . . S11) are positioned in the even rows (e.g., the 2^{nd}, 4^{th}, 7^{th}, and 8^{th} from the top) of the array 450, and the output pins 703 of the source lines (e.g., S2, S4, S6, . . . S10) are positioned in the odd rows (e.g., the 1^{st}, 3^{rd}, 5^{th}, and 7^{th} from the top) of the array 450. The source lines S0 and S13 may not be provided with output pins. The groups of source lines S2S3 and S8S9 are operatively coupled to the driving elements configured to drive the subpixels A only. The groups of source lines S0S1, S6S7, and S12S13 are operatively coupled to the driving elements configured to drive the subpixels B only. The groups of source lines S4S5 and S10S11 are operatively coupled to the driving elements configured to drive the subpixels C only.

FIG. 7B illustrates displaying an image of pure color A by the display 102 in accordance with an embodiment. As shown in FIG. 7B, when displaying an image of pure color A, the source driving circuit 204 may simultaneously apply data signals (e.g., high voltages) to the source lines S2S3 and S8S9, and apply other data signals (e.g., low voltages) to the remaining source lines. FIG. 7C illustrates displaying an image of pure color B by the display 102 in accordance with an embodiment. As shown in FIG. 7C, when displaying an image of pure color B, the source driving circuit 204 may simultaneously apply data signals (e.g., high voltages) to the source lines S0S1, S6S7, and S12S13, and apply other data signals (e.g., low voltages) to the remaining source lines.

FIG. 7D illustrates displaying an image of pure color C by the display 102 in accordance with an embodiment. As shown in FIG. 7D, when displaying an image of pure color C, the source driving circuit 204 may simultaneously apply data signals (e.g., high voltages) to the source lines S4S5 and S10S11, and apply other data signals (e.g., low voltages) to the remaining source lines. As shown in FIGS. 7B-7D, as each source line is only operatively coupled to the driving elements configured to drive the subpixels of the same color, when displaying pure color images, data signals applied to the corresponding source lines may remain at high voltages, while data signals applied to the other source lines may remain at low voltages. Thus, the high-frequency toggling of the source lines between a high voltage and a low voltage is significantly suppressed, and the power consumption is significantly reduced.

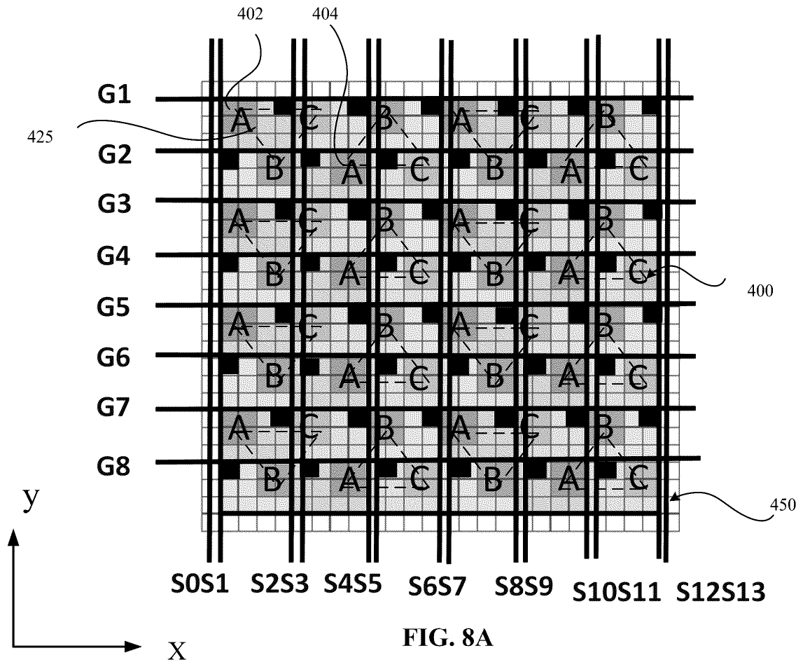

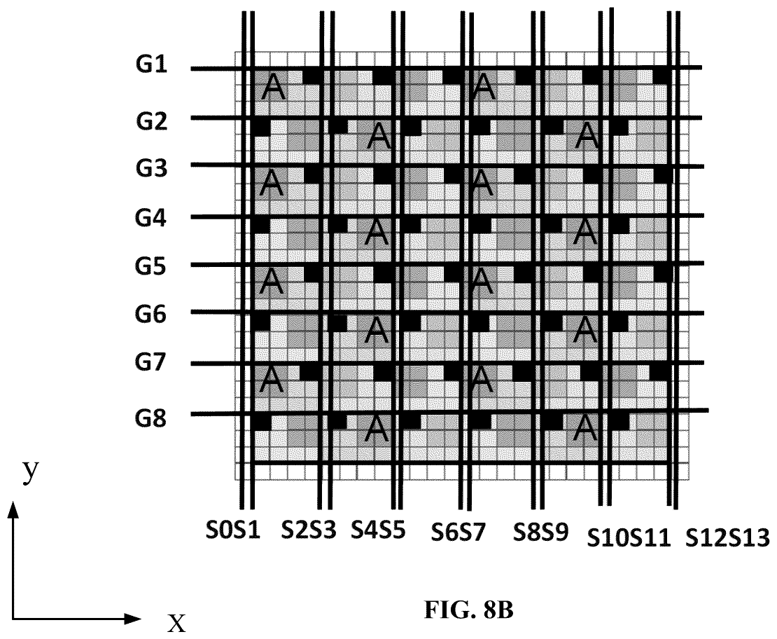

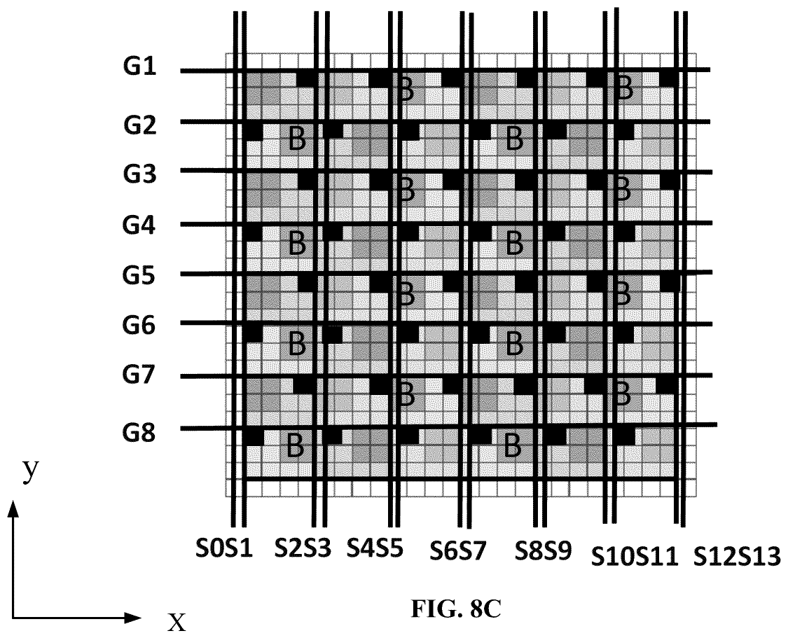

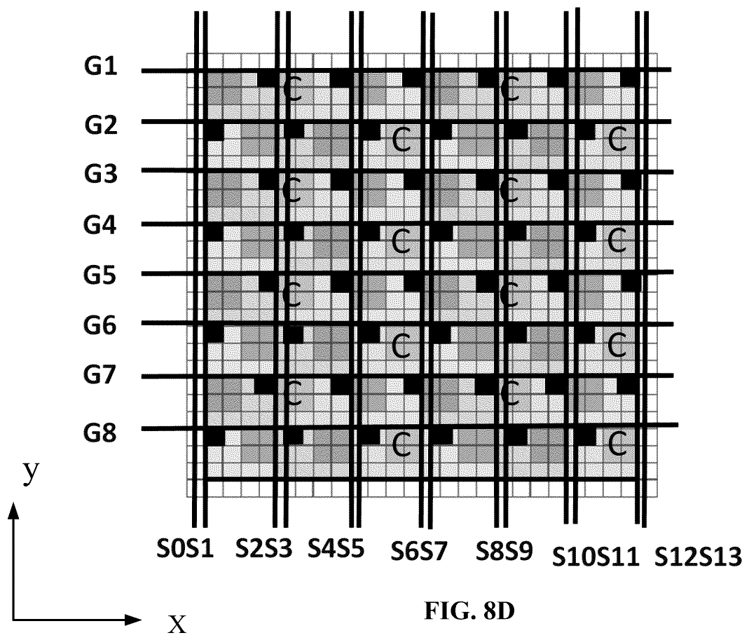

FIG. 8A illustrates an example of an arrangement of gate lines and source lines of driving elements for distributive-driving of subpixels in a display in accordance with an embodiment. FIG. 8A may be, for example, a plan-view (e.g., an x-y sectional view) of the display 102, and depicts one example of an arrangement of gate lines and source lines of driving elements in the example arrangement shown in FIG. 4C for distributive-driving of subpixels in the example arrangement shown in FIG. 4C. Compared to the example shown in FIG. 7A, in the example shown in FIG. 8A, to further increase the compensation time of the pixel circuit, the number of gate lines may be increased, and a time-division multiplexing scheme may be applied in conjunction with the distributive-driving scheme. For example, for the array of pixels 425 arranged in M rows and N columns, the number of gate lines may be doubled to 2*M (i.e., X=2*M), and the number of source lines may be k*N+2 (i.e., Y=k*N+2, e.g., k=3). Thus, when the disclosed display panel 210 has 1920×1080 resolution, 3,242 source lines (3*1080+2) and 3,840 (1920×2) gate lines for 1920×1080 resolution.

As shown in FIG. 8A, the driving elements in each row of the 2*M rows of the array 450 are operatively coupled to one gate line, and are scanned by a scan signal transmitted via the gate line. That is, each row of pixels 425 is provided with two gate lines, with one half of the pixels 425 (e.g., upper half) in each row scanned via one gate line (e.g., G1), and the other half of the pixels 425 (e.g., lower half) in the same row scanned via another gate line (e.g., G2). Further, the gate driving periods of two adjacent gate lines (e.g., G1 and G2) provided to the same row of pixels 425 (or the scan periods of two adjacent columns of subpixels in the same row of pixels 425) are configured to be partially overlapped, the charging time of the pixels may be increased, thereby improving the overall panel refresh rate and enhancing the image quality.

Moreover, the use of separate source lines for respective halves of pixels in the same row ensures that writing new data to one half of pixels does not affect the compensation process of the other half of pixels. That is, the data signals may be written to one half of pixels in each row while allowing the other half of pixels in the same row to complete their compensation operations without interference. This configuration allows each pixel to undergo sufficient compensation for such as threshold voltage variations or aging effects, thereby improving uniformity in luminance and color while maintaining overall display performance.

In the example in FIG. 8A, eight gate line G1 to G8 and seven groups of source lines S0S1 to S12S13 are provided to the array of pixels 425. The first row of pixels 425 are provided with the gate lines G1 and G2, and the gate driving periods of the gate lines G1 and G2 are partially overlapped. The second row of pixels 425 are provided with the gate lines G3 and G4, and the gate driving periods of the gate lines G3 and G4 are partially overlapped. The third row of pixels 425 are provided with the gate lines G5 and G6, and the gate driving periods of the gate lines G5 and G6 are partially overlapped. The fourth row of pixels 425 are provided with the gate lines G7 and G8, and the gate driving periods of the gate lines G7 and G8 are partially overlapped. The groups of source lines S2S3 and S8S9 are operatively coupled to the driving elements configured to drive the subpixels A only. The groups of source lines S0S1, S6S7, and S12S13 are operatively coupled to the driving elements configured to drive the subpixels B only. The groups of source lines S4S5 and S10S11 are operatively coupled to the driving elements configured to drive the subpixels C only.

For example, in a first time period, a scan signal is applied to the gate line G1, and the source driving circuit writes a data signal for the corresponding subpixel (e.g., the subpixel 402, located at the upper half of the pixel in the same row) via the source line S2. In a second, subsequent time period, a scan signal is applied to the gate line G2, and the source driving circuit writes a data signal to the corresponding subpixel (e.g., the subpixel 404, located at the lower half of the pixel in the same row) via the source line S3. The first and second time periods partially overlap, such that that while the data signal is being written to the corresponding subpixel (e.g., the subpixel 404, located at the lower half of the pixel in the same row) via the source line S3, the compensation signal is being written to the corresponding subpixel (e.g., the subpixel 402, located at the upper half of the pixel in the same row) via the source line S2, without interference.

FIG. 8B illustrates displaying an image of pure color A by the display 102 in accordance with an embodiment. FIG. 8C illustrates displaying an image of pure color B by the display 102 in accordance with an embodiment. FIG. 8D illustrates displaying an image of pure color C by the display 102 in accordance with an embodiment. As shown in FIGS. 8B-8D, as each source line is only operatively coupled to the driving elements configured to drive the subpixels of the same color, when displaying pure color images, data signals applied to the corresponding source lines may remain at high voltages, while data signals applied to the other source lines may remain at low voltages. Thus, the high-frequency toggling of the source lines between a high voltage and a low voltage is significantly suppressed, and the power consumption is significantly reduced.

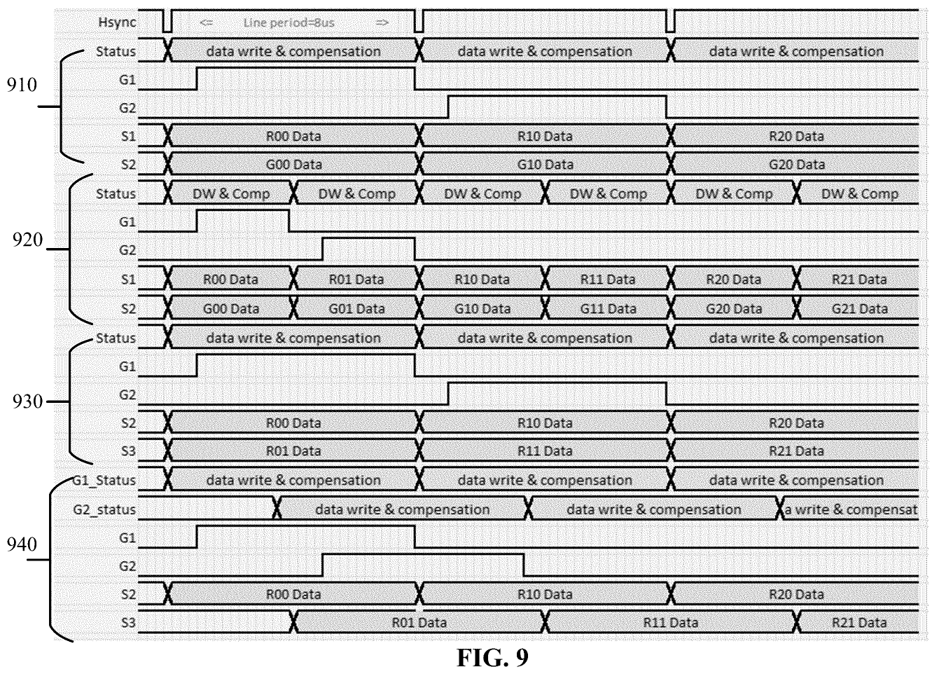

FIG. 9 illustrates a driving scheme 910 for the display 1000 shown in FIG. 10C or the “real-RGB” display 1100 in FIG. 11C. FIG. 9 also illustrates a driving scheme 920 for the display 102 including gate lines and source lines of driving elements shown in FIG. 6A, a driving scheme 930 for the display 102 including gate lines and source lines of driving elements shown in FIG. 7A, and a driving scheme 940 for the display 102 including gate lines and source lines of driving elements shown in FIG. 8A. For discussion purposes, the display 1000 shown in FIG. 10C, the “real-RGB” display 1100 in FIG. 11C, and the display 102 shown in FIG. 6A, FIG. 7A, and FIG. 8A are each presumed to include an array of pixels arranged in M columns and N rows. FIG. 9 illustrates a horizontal synchronization signal (Hsync) at the top, which serves as a time reference, with a line period of approximately 8 μs.

As shown in FIG. 9, in the driving scheme 910 for the display 1000 shown in FIG. 10C or the “real-RGB” display 1100 in FIG. 11C, “Status” waveform indicates periods of data write and compensation for the subpixels. “G1” waveform and “G2” waveform indicate scan signals applied to the gate line G1 and the gate line G2, respectively. “S1” waveform and “S2” waveform indicate periods of data write associated with the source line S1 and the source line S2, respectively. The source line S1 is coupled with the driving elements for red subpixels, and the source line S2 is coupled with the driving elements for green subpixels. In the driving scheme 910, scan signals are sequentially applied to gate lines, enabling the source driving circuit to write corresponding data signals to the subpixels via the source lines. For example, within a first time period, a scan signal is applied to the gate line G1, and the source driving circuit writes data signal (e.g., R00 Data) for the corresponding subpixel via the source line S1, and data signal (e.g., G00 Data) for the corresponding subpixel via the source line S2. During a second, subsequent time period, a scan signal is applied to the gate line G2, and the source driving circuit writes data signal (e.g., R10 Data) for the corresponding subpixel via the source line S1, and data signal (e.g., G10 Data) for the corresponding subpixel via the source line S2. Each of the first time period and the second time period may also include compensation for threshold voltage variations, aging effects, or other pixel characteristics. This sequential process of non-overlapping gate driving periods and corresponding data write and compensation continues for all rows of the display 1000 or 1100.

In the driving scheme 920 for the display 102 shown in FIG. 6A, since the display 102 shown in FIG. 6A is provided with 2*M gate lines, the gate driving period of each gate line is reduced to approximately one-half of that in the driving scheme 910. Accordingly, the corresponding period for data writing and compensation is also reduced to approximately one-half of that shown in the driving scheme 910. “S1” waveform and “S2” waveform indicate periods of data write associated with the source line S1 and the source line S2, respectively. As shown in FIG. 6A, the source line S1 is coupled with the driving elements for red subpixels, and the source line S2 is coupled with the driving elements for green subpixels.

Referring back to FIG. 9, in the driving scheme 920, scan signals are sequentially applied to gate lines, enabling the source driving circuit to write corresponding data signals to the subpixels via the source lines. For example, within a first time period, a scan signal is applied to the gate line G1, and the source driving circuit writes data signal (e.g., R00 Data) for the corresponding subpixel via the source line S1, and data signal (e.g., G00 Data) for the corresponding subpixel via the source line S2. During a second, subsequent time period, a scan signal is applied to the gate line G2, and the source driving circuit writes data signal (e.g., R01 Data) for the corresponding subpixel via the source line S1, and data signal (e.g., G01 Data) for the corresponding subpixel via the source line S2. This sequential process of non-overlapping gate driving periods and corresponding data write and compensation continues for all rows of the display 102.

In the driving scheme 930 for the display 102 shown in FIG. 7A, since the display 102 shown in FIG. 7A is provided with M gate lines, the gate driving period of each gate line is doubled to that in the driving scheme 920. Accordingly, the corresponding period for data writing and compensation is also doubled to that shown in the driving scheme 920. “S2” waveform and “S3” waveform indicate periods of data write associated with the source line S2 and the source line S3, respectively. As shown in FIG. 7A, the source line S2 and the source line S3 form a group coupled with the driving elements for red subpixels.

Referring back to FIG. 9, in the driving scheme 930, scan signals are also sequentially applied to gate lines, enabling the source driving circuit to write corresponding data signals to the subpixels via the source lines. For example, within a first time period, a scan signal is applied to the gate line G1, and the source driving circuit writes data signal (e.g., R00 Data) for the corresponding subpixel via the source line S2, and data signal (e.g., R01 Data) for the corresponding subpixel via the source line S3. During a second, subsequent time period, a scan signal is applied to the gate line G2, and the source driving circuit writes data signal (e.g., R10 Data) for the corresponding subpixel via the source line S2, and data signal (e.g., R11 Data) for the corresponding subpixel via the source line S3. Each of the first time period and the second time period may also include compensation for threshold voltage variations, aging effects, or other pixel characteristics. This sequential process of non-overlapping gate driving periods and corresponding data write and compensation continues for all rows of the display 102.

In the driving scheme 940 for the display 102 shown in FIG. 8A, “G1_Status” waveform indicates periods of data write and compensation associated with the gate line G1 and the source line S2, “G2_Status” waveform indicates periods of data write and compensation associated with the gate line G2 and the source line S3. “G1” waveform and “G2” waveform indicate scan signals applied to the gate line G1 and the gate line G2, respectively. “S2” waveform and “S3” waveform indicate periods of data write associated with the source line S2 and the source line S3, respectively. As shown in FIG. 8A, the source line S2 and the source line S3 form a group coupled with the driving elements for red subpixels.

Although the display 102 shown in FIG. 8A is provided with 2*M gate lines, the gate driving period for each gate line is substantially the same as that shown in the driving scheme 930, with partial overlap between the gate driving periods of two adjacent gate lines (e.g., G1 and G2) provided to the same row of pixels 425. Moreover, the display 102 shown in FIG. 8A is provided with (k*N+2) source lines, and separate source lines (e.g., S2 and S3) are used for the two halves of pixels in the same row, allowing new data to be written to one half of pixels while the other half of pixels to complete its compensation process without interference. Thus, the corresponding period for data writing and compensation remains substantially the same as that in the driving scheme 930.

Referring to FIG. 9, in the driving scheme 940, in a first time period, a scan signal is applied to the gate line G1, and the source driving circuit writes a data signal (e.g., R00 Data) for the corresponding subpixel (e.g., the subpixel 402 shown in FIG. 8A, located at the upper half of the pixel in the same row) via the source line S2. In a second, subsequent time period, a scan signal is applied to the gate line G2, and the source driving circuit writes a data signal (e.g., R01 Data) to the corresponding subpixel (e.g., the subpixel 404 shown in FIG. 8A, located at the lower half of the pixel in the same row) via the source line S3. The first and second time periods partially overlap, such that that while the data signal (e.g., R01 Data) is being written to the corresponding subpixel (e.g., the subpixel 404 shown in FIG. 8A, located at the lower half of the pixel in the same row) via the source line S3, the compensation signal is being written to the corresponding subpixel (e.g., the subpixel 402 shown in FIG. 8A, located at the upper half of the pixel in the same row) via the source line S2, without interference.

The above detailed description of the disclosure and the examples described therein have been presented for the purposes of illustration and description only and not by limitation. It is therefore contemplated that the present disclosure cover any and all modifications, variations or equivalents that fall within the spirit and scope of the basic underlying principles disclosed above and claimed herein.

What is claimed is:

1. An apparatus, comprising:
an array of light emitting elements, wherein the array of light emitting elements corresponds to an array of pixels arranged in M rows and N columns, and a number of the light emitting elements is k times of a number of the pixels, each of M, N, and k is a positive integer;
an array of driving elements configured to drive the array of light emitting elements, wherein a number of the driving elements is k times of a number of the pixels; and
x*M gate lines and ((k/x)*N+1) source lines operatively coupled to the array of driving elements, wherein x is a positive integer,
wherein each source line is operatively coupled to the driving elements configured to drive the light emitting elements that emit lights of a same color.

2. The apparatus of claim 1, wherein:
at least one source line included in the ((k/x)*N+1) source lines is operatively coupled to the driving elements positioned in odd rows in the array of driving elements via a plurality of first output pins, and operatively coupled to the driving elements positioned in even rows in the array of driving elements via a plurality of second output pins;
the first output pins extend toward a first direction; and
the second output pins extend toward a second, different direction.

3. The apparatus of claim 2, wherein the first output pins and the second output pins are alternatively arranged along a column direction of the array of the driving elements, and are spaced apart by a predetermined distance along the column direction of the array of the driving elements.

4. The apparatus of claim 3, wherein the predetermined distance is one driving element.

5. The apparatus of claim 2, wherein the at least one source line is operatively coupled to the driving elements positioned in two adjacent columns in the array of driving elements via the first output pins and the second output pins, respectively.

6. The apparatus of claim 1, wherein:
at least one source line included in the ((k/x)*N+1) source lines includes a first source line and a second source line arranged adjacent to one another;
the first source line is operatively coupled to the driving elements positioned in odd rows in the array of driving elements via a plurality of first output pins; and
the second source line is operatively coupled to the driving elements positioned in even rows in the array of driving elements via a plurality of second output pins.

7. The apparatus of claim 6, wherein the first output pins extend toward a first direction; and the second output pins extend toward a second, different direction.

8. The apparatus of claim 6, wherein the first output pins and the second output pins are alternatively arranged along a column direction of the array of the driving elements, and are spaced apart by a predetermined distance along the column direction of the array of the driving elements.

9. The apparatus of claim 8, wherein the predetermined distance is one driving element.

10. The apparatus of claim 6, wherein the first source line and the second source line are operatively coupled to the driving elements positioned at two adjacent columns in the array of driving elements through the first output pins and the second output pins, respectively.

11. The apparatus of claim 6, wherein gate driving periods of two adjacent gate lines in the x*M gate lines are configured to be partially overlapped.

12. The apparatus of claim 1, wherein x=2, and k=3.

13. The apparatus of claim 1, wherein:
the array of light emitting elements includes a plurality of groups of three light emitting elements that emit lights of different colors;
the three light emitting elements in each group are arranged in a triangular pattern; and
two adjacent groups along a row direction of the array of light emitting elements are arranged in inverted triangular patterns with respect to one another.

14. An apparatus, comprising:
an array of light emitting elements, wherein the array of light emitting elements corresponds to an array of pixels arranged in M rows and N columns, and a number of the light emitting elements is k times of a number of the pixels, each of M, N, and k is a positive integer;
an array of driving elements configured to drive the array of light emitting elements, wherein a number of the driving elements is k times of a number of the pixels; and
M gate lines and ((k/x)*N+1) source lines operatively coupled to the array of driving elements, wherein x is a positive integer,
wherein each source line is operatively coupled to the driving elements configured to drive the light emitting elements that emit lights of a same color.

15. The apparatus of claim 14, wherein:
at least one source line included in the ((k/x)*N+1) source lines includes a first source line and a second source line arranged adjacent to one another;
the first source line is operatively coupled to the driving elements positioned in odd rows in the array of driving elements via a plurality of first output pins; and
the second source line is operatively coupled to the driving elements positioned in even rows in the array of driving elements via a plurality of second output pins.

16. The apparatus of claim 15, wherein the first output pins extend toward a first direction; and the second output pins extend toward a second, different direction.

17. The apparatus of claim 15, wherein:
the first output pins and the second output pins are alternatively arranged along a column direction of the array of the driving elements, and are spaced apart by a predetermined distance along the column direction of the array of the driving elements; and
the predetermined distance is one driving element.

18. The apparatus of claim 15, wherein the first source line is operatively coupled to the driving elements positioned at a first column of two adjacent columns via the first output pins, and the second source line is operatively coupled to the driving elements positioned at a second column of the two adjacent columns via the second output pins.

19. The apparatus of claim 14, wherein x=1, and k=3.

20. The apparatus of claim 14, wherein:
the array of light emitting elements includes a plurality of groups of three light emitting elements that emit lights of different colors;
the three light emitting elements in each group are arranged in a triangular pattern; and
two adjacent groups along a row direction of the array of light emitting elements are arranged in inverted triangular patterns with respect to one another.
